(19) United States
(12) Patent Application Publication
(10) Pub. No.: US 2025/0273134 A1
(43) Pub. Date: Aug. 28, 2025

(54) DISPLAY DRIVING CIRCUIT, CONTROL METHOD THEREFOR, AND DISPLAY APPARATUS

(71) Applicant: Yungu (Gu’an) Technology Co., Ltd., Langfang (CN)

(72) Inventors: Hongjun XIE, Langfang (CN); Wei SU, Langfang (CN); Yong YU, Langfang (CN)

(73) Assignee: Yungu (Gu’an) Technology Co., Ltd., Langfang (CN)

(21) Appl. No.: 19/205,945

(22) Filed: May 12, 2025

Related U.S. Application Data
(63) Continuation of application No. PCT/CN2023/090508, filed on Apr. 25, 2023.

(30) Foreign Application Priority Data
Nov. 29, 2022 (CN) 202211518363.5

(51) Int. Cl. G09G 3/32; G11C 19/28

(52) U.S. Cl. CPC G09G 3/32; G11C 19/287; G09G 2310/0267; G09G 2310/0286; G09G 2310/08; G09G 2330/021; G09G 2340/0435

(57) ABSTRACT

A display driver circuit and a control method therefor, and a display device are disclosed. The display driver circuit includes: at least one first scan driving circuit, the at least one first scan driving circuit including: a plurality of first shift registers arranged in cascade, the first shift register including a register input terminal and a register output terminal, and the first shift registers are configured to output a plurality of scan signals; and at least one cascade control module, the at least one cascade control module being connected between a current-stage register output terminal and a next-stage register input terminal, and the at least one cascade control module being connected to a cascade control signal.

### CROSS-REFERENCE TO RELATED APPLICATIONS

This application is a continuation of International Patent Application No. PCT/CN2023/090508, filed on Apr. 25, 2023, which claims priority to Chinese Patent Application No. 202211518363.5, filed on Nov. 29, 2022, disclosures of both of which are incorporated herein by reference in their entireties.

### FIELD

The present application relates to the field of display technologies, and in particular to a display driver circuit and a control method therefor, and a display device.

### BACKGROUND

With the development of display technologies, the application scenarios of display panels are becoming increasingly diversified, and users' display requirements for display panels are also becoming more varied. For users' demand for simultaneous multi-application display on terminal products, part of the interfaces (e.g., gaming interfaces) in the display screen require high-frequency display to ensure image smoothness, while part of the interfaces can meet display requirements with low frequencies. For this latter part, low-frequency display is desired to reduce product power consumption. However, the display driver circuits in the related art only support full-screen switching frequencies for the entire display panel, making it impossible to meet users' demands for displaying a plurality of scenarios within a single screen on a terminal product. Consequently, it is not possible to implement partitioned multi-frequency display within the same screen.

### SUMMARY

The present application provides a display driver circuit and a control method therefor, and a display device, enabling a display panel to have a partitioned multi-frequency display function.

Embodiments of the present application provide:
a display driver circuit, including: at least one first scan driving circuit,
where the at least one first scan driving circuit includes:
a plurality of first shift registers arranged in cascade, the first shift register including a register input terminal and a register output terminal, where the plurality of first shift registers are configured to output a plurality of scan signals; and
at least one cascade control module, the at least one cascade control module being connected between a current-stage register output terminal and a next-stage register input terminal, and the at least one cascade control module being connected to a cascade control signal, where the at least one cascade control module, in response to the cascade control signal, controls transmission of turn-on potential of the scan signal from the current-stage register output terminal to the next-stage register input terminal, so as to implement multi-frequency display of a display panel in a first direction.

In one embodiment, the at least one cascade control module includes a plurality of cascade control modules, the plurality of cascade control modules being arranged respectively corresponding to at least part of the first shift registers in the at least one first scan driving circuit, and each of the plurality of cascade control modules being arranged between a corresponding current-stage first shift register and a corresponding next-stage first shift register in the at least part of the first shift registers; and the cascade control signal, by controlling switch states of the plurality of cascade control modules, adjusts a position at which the transmission of the turn-on potential of the scan signal to the next-stage register input terminal is cut off during one frame of display.

In one embodiment, the cascade control signal includes: a first cascade control signal; and
the cascade control module includes: a first transistor, and a first electrode of the first transistor is electrically connected to a corresponding current-stage register output terminal, and a second electrode of the first transistor is electrically connected to a corresponding next-stage register input terminal; and a gate of the first transistor is connected to the first cascade control signal.

In one embodiment, turn-off time of the cascade control module during one frame of display is determined based on potential jump time of the first cascade control signal during the one frame of display, thereby determining a partition position for reduced-frequency display of the display panel in the first direction.

In one embodiment, the cascade control signal includes: a plurality of second cascade control signals respectively corresponding to the plurality of cascade control modules;
the cascade control module includes: a second transistor, a gate of the second transistor being connected to a corresponding one of the second cascade control signals, and the second transistor being connected between a corresponding current-stage register output terminal and a corresponding next-stage register input terminal; and
in one embodiment, the at least one first scan driving circuit further includes: a first power terminal and a second power terminal; and the at least one first scan driving circuit further includes:
a first resistor string including a plurality of first resistors connected in series between the first power terminal and the second power terminal, with a plurality of first output terminals tapped from the first resistor string, where the plurality of first output terminals output the second cascade control signals; and the plurality of first output terminals are respectively connected to the plurality of the cascade control modules, and at least one first resistor is disposed between two adjacent ones of the plurality of first output terminals.

In one embodiment, the cascade control signal further includes: a plurality of third cascade control signals respectively corresponding to the plurality of cascade control modules;
the cascade control module further includes: a third transistor, a gate of the third transistor being connected to a corresponding one of the third cascade control signals, and the third transistor and the corresponding second transistor being connected in series between a corresponding current-stage register output terminal and a corresponding next-stage register input terminal; and
in one embodiment, the at least one first scan driving circuit further includes: a third power terminal and a fourth power terminal; and the at least one first scan driving circuit further includes:
a second resistor string including a plurality of second resistors connected in series between the third power terminal and the fourth power terminal, with a plurality of second output terminals tapped from the second resistor string, where the plurality of second output terminals output the third cascade control signals; and the plurality of second output terminals are respectively connected to the plurality of the cascade control modules, and at least one second resistor is disposed between two adjacent ones of the plurality of second output terminals; and
in one embodiment, during one frame of display, a cascade control module at a preset position is turned off in response to the cascade control signal to control a partition position for reduced-frequency display of the display panel in the first direction, where adjustment of the preset position is implemented based on potential adjustment of the first power terminal, the second power terminal, the third power terminal, and the fourth power terminal.

In one embodiment, the at least one first scan driving circuit further includes: at least one auxiliary cut-off module, the at least one auxiliary cut-off module being arranged corresponding to the at least one cascade control module, and a control terminal of the auxiliary cut-off module is connected to a switch control signal, an input terminal of the auxiliary cut-off module is connected to an auxiliary cut-off signal, and an output terminal of the auxiliary cut-off module is connected to the same register input terminal as a cascade control module corresponding to the auxiliary cut-off module;
in one embodiment, the at least one auxiliary cut-off module includes a plurality of auxiliary cut-off modules, and the at least one cascade control module includes a plurality of cascade control modules, the plurality of auxiliary cut-off modules being arranged respectively corresponding to the plurality of cascade control modules, and the auxiliary cut-off modules being connected to the same switch control signal, where on time of the auxiliary cut-off modules during one frame of display is determined based on potential jump time of the switch control signal during the one frame of display; and
in one embodiment, one cascade control module and one auxiliary cut-off module are provided between every two adjacent ones of the first shift registers.

In one embodiment, the current-stage first shift register and the next-stage first shift register are respectively an i^{th}-stage first shift register and an (i+a)^{th}-stage first shift register, where i and a are both positive integers, where
in a case where the i^{th}-stage first shift register outputs turn-on potential of an i^{th}-stage scan signal and the (i+a)^{th}-stage first shift register outputs turn-on potential of an (i+a)^{th}-stage scan signal, during a phase when the i^{th}-stage first shift register outputs the turn-on potential of the i^{th}-stage scan signal, the cascade control signal controls a cascade control module between the i^{th}-stage first shift register and the (i+a)^{th}-stage first shift register to be turned on, and the switch control signal controls an auxiliary cut-off module between the i^{th}-stage first shift register and the (i+a)^{th}-stage first shift register to be turned off; and in a case where the i^{th}-stage first shift register outputs the turn-on potential of the i^{th}-stage scan signal and the (i+a)^{th}-stage first shift register outputs cutoff potential of the (i+a)^{th}-stage scan signal, during the phase when the i^{th}-stage first shift register outputs the turn-on potential of the i^{th}-stage scan signal, the cascade control signal controls the cascade control module between the i^{th}-stage first shift register and the (i+a)^{th}-stage first shift register to be turned off, and the switch control signal controls the auxiliary cut-off module between the i^{th}-stage first shift register and the (i+a)^{th}-stage first shift register to be turned on.

In one embodiment, the display driver circuit further includes: a first potential signal line and a second potential signal line, the first potential signal line being configured to provide a first potential signal to the plurality of first shift registers, and the second potential signal line being configured to provide a second potential signal to the plurality of first shift registers, where
when the potential of the first potential signal is cutoff potential, the first potential signal is reused as the auxiliary cut-off signal; and when the potential of the second potential signal is the cutoff potential, the second potential signal is reused as the auxiliary cut-off signal.

In one embodiment, the cascade control signal includes: a first cascade control signal; and the cascade control module includes: a first transistor, and a gate of the first transistor is connected to the first cascade control signal, a first electrode of the first transistor is electrically connected to a corresponding current-stage register output terminal, and a second electrode of the first transistor is electrically connected to a corresponding next-stage register input terminal; and
the auxiliary cut-off module includes: a fourth transistor, and a gate of the fourth transistor is connected to the switch control signal, a first electrode of the fourth transistor is connected to the auxiliary cut-off signal, and a second electrode of the fourth transistor is electrically connected to a corresponding next-stage register input terminal.

In one embodiment, the first transistor has the same channel type as that of the fourth transistor, and the first cascade control signal has an opposite phase to that of the switch control signal; or
the first transistor has a different channel type from that of the fourth transistor, and the first cascade control signal is reused as the switch control signal.

In one embodiment, the first transistor has the same channel type as that of the fourth transistor, and the first cascade control signal is reused as the auxiliary cut-off signal.

In one embodiment, the display driver circuit further includes: a plurality of pixel driver circuits and a plurality of first scan lines, where the plurality of pixel driver circuits are arranged in an array, and each row of pixel driver circuits is electrically connected to at least one of the plurality of first scan lines; and register output terminals in the at least one first scan driving circuit are electrically connected to the first scan lines.

In one embodiment, the pixel driver circuit includes: a driving module, a data writing module, a threshold compensation module, and a light emission control module, where
the driving module is connected between the light emission control module and a light-emitting device, and the driving module is configured to generate a driving current; the data writing module is electrically connected to a first terminal of the driving module, and the data writing module is configured to transmit a data voltage to the driving module; the threshold compensation module is connected between a control terminal and a second terminal of the driving module, and the threshold compensation module is configured to compensate for a threshold voltage of the driving module; and the first scan line is electrically connected to control terminals of threshold compensation modules in a corresponding row of pixel driver circuits; and
in one embodiment, the pixel driver circuit further includes: a first reset module electrically connected to the control terminal of the driving module, the first reset module being configured to reset the control terminal of the driving module; and the display driver circuit further includes: a plurality of second scan lines, the second scan line being electrically connected to control terminals of first reset modules in a corresponding row of pixel driver circuits, and
in one embodiment, the register output terminals in the at least one first scan driving circuit are electrically connected to the second scan lines, where a second scan line connected to a j^{th} row of pixel driver circuits is electrically connected to a j^{th}-stage register output terminal, and a first scan line connected to the j^{th} row of pixel driver circuits is electrically connected to a (j+b)^{th}-stage register output terminal, where j and b are both positive integers.

In one embodiment, the at least one first scan driving circuit includes a first-side first scan driving circuit and a second-side first scan driving circuit, the first-side first scan driving circuit and the second-side first scan driving circuit being respectively disposed on two sides of the plurality of pixel driver circuits; and first shift registers of corresponding stages in the first-side first scan driving circuit and the second-side first scan driving circuit being connected to the same first scan line;
each of at least part of the plurality of first scan lines includes at least two sub-scan lines; and
the display driver circuit further includes: at least one split-screen control module, the at least one split-screen control module including a plurality of split-screen switch units, where the plurality of split-screen switch units are arranged respectively corresponding to the at least part of the plurality of first scan lines; each of the plurality of split-screen switch units is connected between two adjacent sub-scan lines in the same first scan line; and when each of the plurality of split-screen switch units is turned off in response to a split-screen control signal, the first-side first scan driving circuit and the second-side first scan driving circuit respectively transmit scan signals to sub-scan lines on both sides of the split-screen switch unit.

In one embodiment, at the same moment, the number of split-screen switch units on the same first scan line that are in an off state is less than or equal to one; and
the plurality of split-screen switch units in the same split-screen control module are connected to the same split-screen control signal; and
in one embodiment, a cascade control signal connected to the first-side first scan driving circuit is a first-side cascade control signal, and a cascade control signal connected to the second-side first scan driving circuit is a second-side cascade control signal, the first-side cascade control signal being different from the second-side cascade control signal.

In one embodiment, when turn-on potential of scan signals is simultaneously transmitted on two sub-scan lines respectively connected to both ends of one split-screen switch unit among the plurality of split-screen switch units, the split-screen control signal controls the one split-screen switch unit among the plurality of split-screen switch units to be turned on.

In one embodiment, each of the at least part of the first scan lines includes a first sub-scan line and a second sub-scan line, the first sub-scan line being connected to the first-side first scan driving circuit, and the second sub-scan line being connected to the second-side first scan driving circuit; and
each of the plurality of split-screen switch units is separately electrically connected to a corresponding first sub-scan line and second sub-scan line; and
in one embodiment, the first sub-scan line has the same length as that of the second sub-scan line.

In one embodiment, each of the at least part of the first scan lines includes a third sub-scan line, a fourth sub-scan line, and a fifth sub-scan line; and the at least one split-screen control module includes: a first split-screen control module and a second split-screen control module, where
the third sub-scan line is connected to the first-side first scan driving circuit, the first split-screen control module is connected between the third sub-scan line and the fourth sub-scan line, the second split-screen control module is connected between the fourth sub-scan line and the fifth sub-scan line, and the fifth sub-scan line is connected to the second-side first scan driving circuit;
in one embodiment, within the same display frame, during a data writing process of part of the rows of pixel driver circuits, the first split-screen control module is turned on and the second split-screen control module is turned off, and during a data writing process of other rows of pixel driver circuits, the first split-screen control module is turned off and the second split-screen control module is turned on; and
in one embodiment, the split-screen control signal includes a first split-screen control signal and a second split-screen control signal, the first split-screen control module being connected to the first split-screen control signal, and the second split-screen control module being connected to the second split-screen control signal; and a transistor in a split-screen switch unit in the first split-screen control module has a different channel type from that of a transistor in a split-screen switch unit in the second split-screen control module, and the first split-screen control signal is reused as the second split-screen control signal.

In one embodiment, the split-screen switch unit includes: a fifth transistor, and a gate of the fifth transistor is connected to the split-screen control signal, and a first electrode of the fifth transistor and a second electrode of the fifth transistor are respectively connected to two adjacent sub-scan lines in the same first scan line.

Correspondingly, embodiments of the present application further provide a control method for a display driver circuit, which is used to control the display driver circuit according to any embodiment of the present application, the control method including:
obtaining a target partition position of a display panel in a first direction; and determining a cascade control signal during each frame of display based on the target partition position, and controlling a switch state of the cascade control module during each frame of display based on the cascade control signal.

In one embodiment, the at least one cascade control module includes a plurality of cascade control modules; the display panel includes at least one target partition position; and
a display process of the display panel includes a plurality of types of display frames, the plurality of types of display frames include a first active frame and at least one type of second active frame, with the type of the second active frame corresponding to the target partition position, respectively, where
in the first active frame, the cascade control signal controls all of the plurality of cascade control modules to remain turned on; and
in the second active frame, the cascade control signal controls turn-off time of all of the plurality of cascade control modules, or controls a cascade control module at a preset position to be turned off, so that the display panel displays based on the target partition position corresponding to the second active frame.

Correspondingly, embodiments of the present application further provide a display device, including: a display driver circuit according to any embodiment of the present application.

For the display driver circuit according to the embodiments of the present application, at least one cascade control module is provided in the first scan driving circuit, and the cascade control signal, by controlling the switch state of the cascade control module, can control whether the turn-on potential of the scan signal output by the first shift register can be propagated stage by stage. By cutting off the transmission of the turn-on potential of the scan signal to the next-stage first shift register, partitioned display of the display panel in the first direction during the same frame of display can be achieved, with different refresh frequencies for different display regions, thereby enriching the display functionality of the display panel. In summary, compared with the prior art, the embodiments of the present application can enable the display panel to have a partitioned multi-frequency display function.

It should be understood that the content described in this section is not intended to identify key or important features of embodiments of the present application, and not intended to limit the scope of the present application. Other features of the present application will become easy to understand through the following description.

### BRIEF DESCRIPTION OF THE DRAWINGS

In order to illustrate the embodiments of the present application more clearly, the drawings required for the description of the embodiments will be briefly introduced below. The drawings in the following description are only for some of the embodiments of the present application.

FIG. 1 is a schematic diagram of a structure of a display driver circuit according to an embodiment of the present application;

FIG. 2 is a schematic diagram of a structure of another display driver circuit according to an embodiment of the present application;

FIG. 3 is a schematic diagram of a structure of a further display driver circuit according to an embodiment of the present application;

FIG. 4 is a schematic diagram of a structure of a further display driver circuit according to an embodiment of the present application;

FIG. 5 is a schematic diagram of a structure of a further display driver circuit according to an embodiment of the present application;

FIG. 6 is a schematic diagram of a structure of a display panel according to an embodiment of the present application;

FIG. 7 is a timing diagram of driving signals for a display frame according to an embodiment of the present application;

FIG. 8 is a timing diagram of driving signals for another display frame according to an embodiment of the present application;

FIG. 9 is a timing diagram of driving signals for a further display frame according to an embodiment of the present application;

FIG. 10 is a schematic diagram of a driving timing sequence of a display panel according to an embodiment of the present application;

FIG. 11 is a schematic diagram of a driving timing sequence of another display panel according to an embodiment of the present application;

FIG. 12 is a schematic diagram of a structure of a further display driver circuit according to an embodiment of the present application;

FIG. 13 is a schematic diagram of a structure of a further display driver circuit according to an embodiment of the present application;

FIG. 14 is a schematic diagram of a driving timing sequence of a further display panel according to an embodiment of the present application;

FIG. 15 is a schematic diagram of a structure of a further display driver circuit according to an embodiment of the present application;

FIG. 16 is a schematic diagram of a driving timing sequence of a further display panel according to an embodiment of the present application;

FIG. 17 is a schematic diagram of a structure of a further display driver circuit according to an embodiment of the present application;

FIG. 18 is a schematic diagram of a power terminal voltage setting mode according to an embodiment of the present application;

FIG. 19 is a schematic diagram of another power terminal voltage setting mode according to an embodiment of the present application;

FIG. 20 is a schematic diagram of a structure of a pixel driver circuit according to an embodiment of the present application;

FIG. 21 is a schematic diagram of a driving timing sequence of a pixel driver circuit according to an embodiment of the present application;

FIG. 22 is a schematic diagram of a structure of another display panel according to an embodiment of the present application;

FIG. 23 is a schematic diagram of a structure of a first shift register according to an embodiment of the present application;

FIG. 24 is a schematic diagram of a driving timing sequence of a first shift register according to an embodiment of the present application;

FIG. 25 is a schematic diagram of a structure of another pixel driver circuit according to an embodiment of the present application;

FIG. 26 is a schematic diagram of a driving timing sequence of another pixel driver circuit according to an embodiment of the present application;

FIG. 27 is a schematic diagram of a structure of another first shift register according to an embodiment of the present application;

FIG. 28 is a schematic diagram of a driving timing sequence of another first shift register according to an embodiment of the present application;

FIG. 29 is a schematic diagram of a driving timing sequence of a further pixel driver circuit according to an embodiment of the present application;

FIG. 30 is a schematic diagram of a structure of a further display panel according to an embodiment of the present application;

FIG. 31 is a schematic diagram of a structure of a further display panel according to an embodiment of the present application;

FIG. 32 is a schematic diagram of a driving timing sequence of a further display panel according to an embodiment of the present application;

FIG. 33 is a schematic diagram of a driving timing sequence of a further display panel according to an embodiment of the present application;

FIG. 34 is a schematic diagram of a driving timing sequence of a further display panel according to an embodiment of the present application;

FIG. 35 is a schematic diagram of a driving timing sequence of a further display panel according to an embodiment of the present application;

FIG. 36 is a schematic diagram of a driving timing sequence of a further display panel according to an embodiment of the present application;

FIG. 37 is a schematic diagram of a driving timing sequence of a further display panel according to an embodiment of the present application;

FIG. 38 is a schematic diagram of a driving timing sequence of a further display panel according to an embodiment of the present application;

FIG. 39 is a schematic diagram of a structure of a further display panel according to an embodiment of the present application;

FIG. 40 is a schematic diagram of a driving timing sequence of a further display panel according to an embodiment of the present application; and

FIG. 41 is a schematic diagram of a structure of a further display panel according to an embodiment of the present application.

### DETAILED DESCRIPTION OF THE EMBODIMENTS

The embodiments of the present application will be better understood and the following will provide a clear and complete description of the embodiments of the present application with reference to the accompanying drawings of the embodiments of the present application. It is evident that the described embodiments are merely part of the embodiments of the present application and not all of the embodiments.

It should be noted that the terms such as “first” and “second” in the specification and the claims of the present application and in the aforementioned accompanying drawings are used to distinguish similar objects, and do not necessarily describe a specific order or sequence. It should be understood that the data used in this way can be interchanged where appropriate, such that the embodiments of the present application described herein can be implemented in a sequence other than those illustrated or described herein. In addition, the terms “comprising/including” and “having,” as well as any variations thereof, are intended to cover non-exclusive inclusion.

To better explain the embodiments of the present application, a brief description of the structure and driving process of the display driver circuit in the display panel will be given below.

The display driver circuit in the display panel includes: a scan driving circuit arranged in a non-active area and pixel driver circuits arranged in an array in the active area. The scan driving circuit includes shift registers arranged in cascade, and the scan driving circuit can operate in a single-side driving mode or a dual-side driving mode. The pixel driver circuit, together with light-emitting devices, forms one sub-pixel. Each sub-pixel serves as one smallest display unit, and a plurality of sub-pixels of different colors form one pixel, thereby enabling color display. Each stage of shift register is correspondingly connected to one scan line and provides a scan signal to a corresponding row of sub-pixels through the scan line, while each column of sub-pixels is correspondingly connected to one data line.

During the image display process, data writing is performed on each pixel driver circuit by means of row-by-row scanning. That is, the shift register provides scan signals to the pixel driver circuits via the scan line. Corresponding to the duration of the turn-on potential of the scan signal, the data voltage on the data line is transmitted to the corresponding pixel driver circuit to achieve data writing, and each sub-pixel displays based on the data voltage. When the scan line provides cutoff potential, the data voltage on the data line cannot be transmitted to the corresponding pixel driver circuit, and no data writing is performed. For example, when scanning the 1^{st} row of sub-pixels, the scan line corresponding to the 1^{st} row of sub-pixels provides turn-on potential to the 1^{st} row of pixel driver circuits, while the scan lines corresponding to the other rows of sub-pixels provide cutoff potential, so that the data voltages on the data lines are transmitted to the 1^{st} row of sub-pixels. At any given time, only one shift register outputs the turn-on potential of the scan signal.

For a display panel capable of switching display frequencies, the display frames of the sub-pixel can be divided into active frames and idle frames. In an active frame, the shift register provides turn-on potential to a corresponding row of pixel driver circuits, causing the data voltage to be written into the pixel driver circuits; and in an idle frame, the shift register provides cutoff potential to the corresponding row of pixel driver circuits, and the pixel driver circuits do not perform data writing.

The refresh frequency can be understood as the number of active frames contained in a unit of time. By way of example, only active frames may be included in high-frequency display, while low-frequency display is implemented by means of frame skipping. For instance, at a refresh frequency of f, the display frames of the display panel include only active frames. By way of example, when f=60 Hz, the display panel refreshes 60 display frames within 1 second, with each frame duration=1 s/60=16.67 ms. When the refresh frequency decreases, idle frames are inserted between adjacent active frames, while the number of display frames within a unit of time remains unchanged, and the display duration of each display frame also remains unchanged. When the refresh frequency is f/2, one idle frame is inserted between every two adjacent active frames, that is, odd-numbered frames are active frames, and even-numbered frames are idle frames. When the refresh frequency is f/3, two idle frames are inserted between every two adjacent active frames. By analogy, when the refresh frequency is f/(N+1), N idle frames are inserted between every two adjacent active frames.

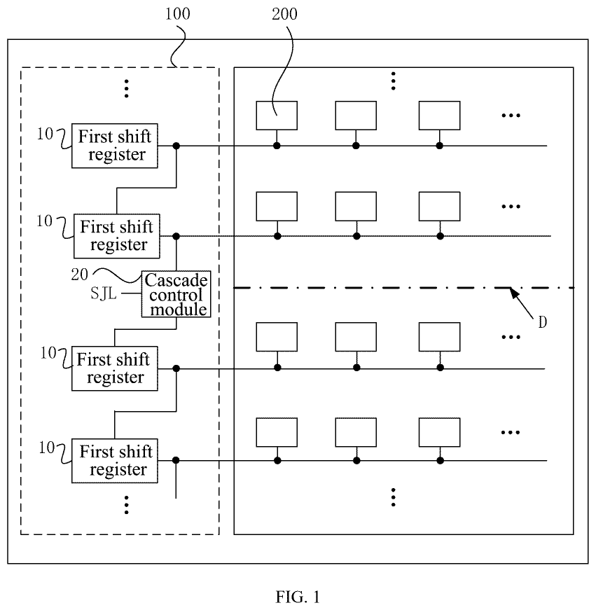

An embodiment of the present application provides a display driver circuit to implement a driving scheme for providing different refresh frequencies to different display regions of the display panel. FIG. 1 is a schematic diagram of a structure of a display driver circuit according to an embodiment of the present application. With reference to FIG. 1, the display driver circuit includes: at least one first scan driving circuit 100. In FIG. 1, an example is given where the display driver circuit includes one first scan driving circuit 100. When the display driver circuit includes a plurality of first scan driving circuits 100, the plurality of first scan driving circuits 100 can have the same structure. The first scan driving circuit 100 includes: a plurality of first shift registers 10 arranged in cascade, and at least one cascade control module 20. Each first shift register 10 includes a register input terminal and a register output terminal. Each cascade control module 20 is connected between the corresponding current-stage register output terminal and next-stage register input terminal, with the control terminal of the cascade control module 20 being connected to the cascade control signal SJL. Each cascade control module 20, in response to the cascade control signal SJL, controls transmission of turn-on potential of the scan signal from the current-stage register output terminal to the next-stage register input terminal, so as to implement multi-frequency display of a display panel in a first direction (i.e., the sub-pixel column direction).

It can be understood that when the stages of first shift registers 10 are connected in cascade, during the process of the first shift registers 10 outputting the scan signal stage by stage, the turn-on potential of the current-stage scan signal is transmitted to the next-stage first shift register 10, serving as the start signal for the next-stage first shift register 10 to trigger continued outputting of the turn-on potential of the scan signal from the next-stage first shift register 10, thereby achieving sequential shifting of the turn-on pulse of the scan signal.

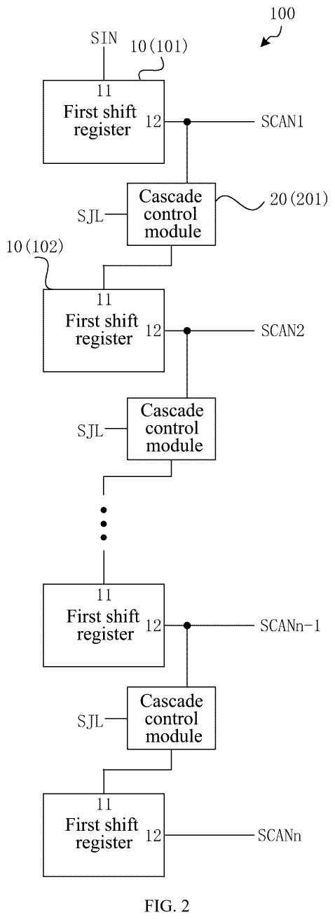

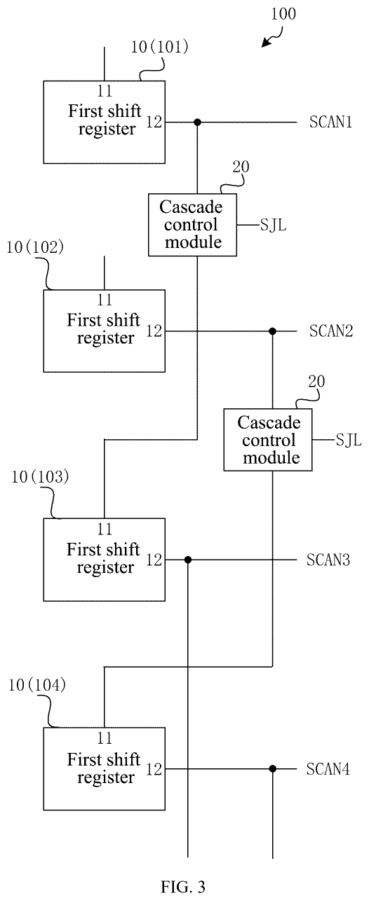

It should be noted that the current-stage first shift register and the next-stage first shift register are respectively the i^{th}-stage first shift register and the (i+a)^{th}-stage first shift register in the first scan driving circuit 100, where i and a are both positive integers. By way of example, as shown in FIG. 2, when the stages of first shift registers are cascaded in sequence, a=1, and when the current-stage first shift register is the 1^{st}-stage first shift register 101, the next-stage first shift register is the 2^{nd}-stage first shift register 102. In contrast, when the stages of shift registers are not cascaded in sequence, a>1, and the next-stage first shift register is not the immediate next stage of first shift register to the current-stage first shift register. As shown in FIG. 3, when a=2, odd-numbered-stage first shift registers are cascaded in sequence, and even-numbered-stage first shift registers are cascaded in sequence. When the current-stage first shift register is the 1^{st}-stage first shift register 101, the next-stage first shift register is the 3^{rd}-stage first shift register 103. In the following embodiments, for ease of explanation, the connection structure in which the stages of first shift registers are cascaded in sequence in FIG. 2 will be used as an example for explanation.

The cascade control module 20, provided between two stages of first shift registers 10, when turned off in response to the cascade control signal SJL, disconnects the connection between the current-stage register output terminal 12 and the next-stage register input terminal 11, thereby blocking the stage-by-stage transmission path of the scan signal and cutting off the downward transmission of the turn-on potential of the scan signal. As a result, the sub-pixel rows before the disconnection position are controlled by the turn-on potential to be in the active frame, while the sub-pixel rows after the disconnection position are controlled by the cutoff potential to be in the idle frame, thereby implementing multi-frequency display of the display panel in the first direction. Specifically, in this exemplary embodiment, by arranging the plurality of cascade control modules 20, a driving scheme for multi-frequency display of the display panel in the first direction with the refresh frequency transitioning from high to low is implemented. In other embodiments, on the basis of providing the cascade control module 20, a driving scheme in which the refresh frequency transitions from low to high can also be implemented by transmitting a start signal to the next-stage register input terminal 11.

By way of example, the number of cascade control modules 20 can be the same as that of target partition positions D, and the plurality of cascade control modules are arranged in one-to-one correspondence with the target partition positions of the display panel. Alternatively, the number of cascade control modules 20 can be greater, allowing the partition positions of the display panel in the first direction to be adjustable.

For the display driver circuit according to the embodiments of the present application, at least one cascade control module 20 is provided in the first scan driving circuit 100, and the cascade control signal SJL, by controlling the switch state of the cascade control module 20, can control whether the turn-on potential of the scan signal output by the first shift register 10 can be propagated stage by stage. By cutting off the transmission of the turn-on potential of the scan signal to the next-stage first shift register 10, partitioned display of the display panel in the first direction during the same frame of display can be achieved, with different refresh frequencies for different display regions, thereby enriching the display functionality of the display panel. In summary, compared with the related art, the embodiments of the present application can enable the display panel to have a partitioned multi-frequency display function.

With continued reference to FIG. 2, on the basis of the aforementioned implementations, in one embodiment, the at least one cascade control module 20 includes a plurality of cascade control modules 20. The plurality of cascade control modules 20 are arranged respectively corresponding to at least part of the first shift registers 10 in the first scan driving circuit 100, for example, being correspondingly connected to part of or all of the first shift registers 10. Each of the plurality of cascade control modules 20 is arranged between a corresponding current-stage first shift register 10 and a corresponding next-stage first shift register 10 in the at least part of the first shift registers 10. Each of the plurality of cascade control modules 20 responds to the cascade control signal SJL, where the cascade control signal SJL, by controlling switch states of the plurality of cascade control modules 20, adjusts a position at which the transmission of the turn-on potential of the scan signal to the next-stage register input terminal 11 is cut off during one frame of display, thereby adjusting a partition position for reduced-frequency display of the display panel in the first direction.

Specifically, taking the cascade control module 201 provided between the 1^{st}-stage first shift register 101 and the 2^{nd}-stage first shift register 102 as an example, when the cascade control module 201 is turned off, the connection between the register output terminal 12 of the 1^{st}-stage first shift register 101 and the register input terminal 11 of the 2^{nd}-stage first shift register 102 is disconnected. During one frame of display, the turn-on potential of the 1^{st}-stage scan signal SCAN1 cannot be transmitted to the 2^{nd}-stage register input terminal, and thus cannot trigger the output of the turn-on potential by the 2^{nd}-stage first shift register 102. As a result, the 2^{nd}-stage first shift register 102 continuously outputs the cutoff potential during that frame of display. Thus, a row of sub-pixels corresponding to the 1^{st}-stage first shift register 101 are in an active frame, and a row of sub-pixels corresponding to the 2^{nd}-stage first shift register 102 are in an idle frame, and the position between the above two rows of sub-pixels is a partition position for reduced-frequency display of the display panel.

Based on the aforementioned analysis, when a plurality of cascade control modules 20 are provided in the first scan driving circuit, the cascade control signal SJL, by controlling the switch states of the plurality of cascade control modules 20 during each frame of display, can change the position at which the stage-by-stage transmission of the scan signal is cut off, thereby adjusting the partition positions for reduced-frequency display of the display panel. Specifically, during one frame of display, within the scan time for the row of sub-pixels immediately preceding the target display partition position, the cascade control signal SJL controls the cascade control module 20 between two first shift registers 10 respectively connected to that row of sub-pixels and the next row of sub-pixels to disconnect, thereby achieving the reduced-frequency display in that display frame based on the target display partition position. By way of example, during one frame of display, the cascade control signal SJL can control the time at which each stage of cascade control module 20 is switched from on to off, or control the turn-off of the cascade control module 20 corresponding to the target partition position, thereby achieving the aforementioned control process.

For the display driver circuit according to the embodiment of the present application, by arranging a plurality of cascade control modules 20, the position at which the transmission of the turn-on potential of the scan signal is cut off within each display frame is made adjustable, thereby allowing the partition positions for reduced-frequency display of the display panel to be adjustable. This enhances the display functionality of the display panel and makes the driving process of the display panel more flexible.

On the basis of the aforementioned implementations, in one embodiment, one cascade control module 20 can be provided between every two adjacent first shift registers 10, such that the stage-by-stage propagation of the scan signal can be interrupted at any row position on the display screen, thereby allowing the partition positions to be unrestricted by the positions at which the plurality of cascade control modules 20 are provided. In the actual driving process, the operational state of any cascade control module 20 can be controlled at any time as needed, making the partition positions of the display panel arbitrarily adjustable.

In the first scan driving circuit 100 as shown in FIG. 2, when a certain cascade control module 20 is turned off, the next-stage register input terminal 11 connected to it becomes floating, and there is no voltage input, which results in a risk of unstable output states in the next-stage first shift register 10.

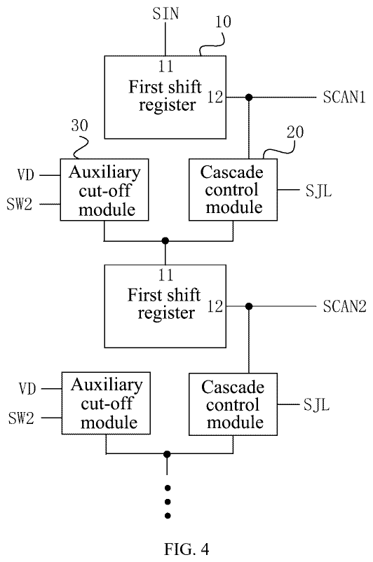

To address the above situation, the inventors propose an improved embodiment. FIG. 4 is a schematic diagram of a structure of a further display driver circuit according to an embodiment of the present application. With reference to FIG. 4, on the basis of the aforementioned implementations, in one embodiment, the first scan driving circuit 100 is further provided with: at least one auxiliary cut-off module 30. The auxiliary cut-off module 30 is arranged corresponding to the plurality of cascade control modules 20. By way of example, there may be a plurality of auxiliary cut-off modules 30, and they are arranged respectively corresponding to the plurality of cascade control modules 20. A control terminal of the auxiliary cut-off module 30 is connected to a switch control signal SW2, an input terminal of the auxiliary cut-off module 30 is connected to an auxiliary cut-off signal VD, and an output terminal of the auxiliary cut-off module 30 is connected to the same register input terminal 11 as a cascade control module 20 corresponding to the auxiliary cut-off module 30.

Here, the switch control signal SW2 can control the corresponding auxiliary cut-off module 30 to be turned on when the cascade control module 20 is turned off, so as to transmit the auxiliary cut-off signal VD to the next-stage register input terminal 11 to prevent the next-stage register input terminal 11 from floating, thereby enabling the next-stage first shift register 10 to stably output the cutoff potential of the scan signal. By way of example, the auxiliary cut-off signal VD may be a direct-current voltage signal, and the potential of the auxiliary cut-off signal VD can be the cutoff potential of the scan signal.

On the basis of the aforementioned implementations, in one embodiment, the cascade control signal SJL and the switch control signal SW2 can both be provided by the mainboard of the terminal apparatus, and enter the screen body via the driver integrated circuit (IC). Alternatively, they can be directly provided by the driver IC. The mainboard of the terminal apparatus can have the capability of detecting the information of each frame of image to determine the display state of the display panel during each frame of display and the refresh frequency corresponding to each sub-active area.

On the basis of the aforementioned implementations, in one embodiment, within each display frame, there are a plurality of control methods for the cascade control module 20, which will be explained separately below.

It should be noted that, in the display panel, when the corresponding connection relationships for the scan driving circuits and the pixel driver circuits are different, the sub-pixel row correspondingly connected to the i^{th}-stage first shift register 10 can be the i^{th} row of sub-pixels, or the (i−1)^{th} row of sub-pixels, or it can be another row of sub-pixels determined based on the connection relationship. In the following description, for the convenience of explaining the operational process of the display driver circuit, the case where the i^{th}-stage first shift register 10 is correspondingly connected to the i^{th} row of sub-pixels will be taken as an example for illustration.

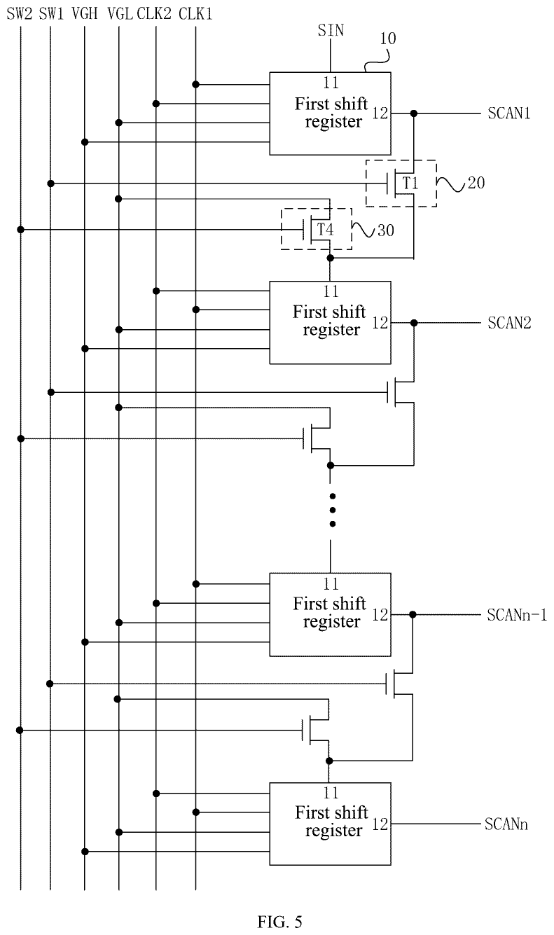

FIG. 5 is a schematic diagram of a structure of a further display driver circuit according to an embodiment of the present application. With reference to FIG. 5, in an implementation, in one embodiment, the cascade control signal SJL includes: a first cascade control signal SW1, where the plurality of cascade control modules 20 are connected to the same first cascade control signal SW1, and all of the plurality of cascade control modules 20 are simultaneously turned on or off in response to the first cascade control signal SW1. This arrangement can simplify the structure of the display driver circuit, reduce the number of output ports of the driver IC, lower the costs, and make the display driver circuit easier to implement and apply. By adjusting the potential jump time during one frame of display, the first cascade control signal SW1 adjusts the turn-off time of the plurality of cascade control modules 20 during one frame of display, thereby achieving the adjustment of the partition positions for reduced-frequency display of the display panel. The duration for which the cascade control module 20 is turned on during one frame of display determines the number of sub-pixel rows that transmit the scan signals and are refreshed.

Since only one first shift register 10 outputs turn-on potential at any given moment while other first shift registers 10 all output cutoff potential, even if the first cascade control signal SW1 controls all of the plurality of cascade control modules 20 to be simultaneously turned on, only the stage of first shift register 10 that outputs the turn-on potential can function to transmit this turn-on potential to the next-stage first shift register 10, whereas other first shift registers 10 can only receive cutoff potential. Therefore, simultaneous turn-on of all cascade control modules 20 will not cause a plurality of first shift registers 10 to receive the start signal at the same moment, nor will it cause a plurality of first shift registers 10 to output the turn-on potential at the same moment, thus not affecting the normal driving of the display panel. By contrast, simultaneous turn-off of all cascade control modules 20 is similarly equivalent to only affecting the stage of first shift register 10 that is outputting the turn-on potential, preventing the turn-on potential from being transmitted to the next-stage first shift register 10, whereas whether the connections between the other stages of first shift registers 10 are cut off does not affect the continuous output of the cutoff potential by the other stages of first shift registers 10. Therefore, simultaneous turn-on/off of all of the plurality of cascade control modules 20 does not affect the normal driving of the display panel, and all of the plurality of cascade control modules 20 can be connected to the same stage of first cascade control signal SW1.

Correspondingly, simultaneous turn-on/off of all auxiliary cut-off modules 30 will not affect the normal driving of the display panel, and all of the auxiliary cut-off modules 30 can be connected to the same switch control signal SW2. The potential jump time of the switch control signal SW2 during one frame of display determines on time of the auxiliary cut-off modules 30 during the one frame of display. The first cascade control signal SW1, in conjunction with the switch control signal SW2, can implement the regulation of partitioned multi-frequency display positions of the display panel. In a case where the i^{th}-stage first shift register outputs turn-on potential of an i^{th}-stage scan signal and the (i+a)^{th}-stage first shift register (the next-stage first shift register to the i^{th}-stage first shift register) outputs turn-on potential of an (i+a)^{th}-stage scan signal, during a phase when the i^{th}-stage first shift register 10 outputs the turn-on potential of the i^{th}-stage scan signal, the cascade control signal SJL controls a cascade control module 20 between the i^{th}-stage first shift register and the (i+a)^{th}-stage first shift register to be turned on, and the switch control signal SW2 controls an auxiliary cut-off module 30 between the i^{th}-stage first shift register and the (i+a)^{th}-stage first shift register to be turned off. In a case where the i^{th}-stage first shift register outputs the turn-on potential of the i^{th}-stage scan signal and the (i+a)^{th}-stage first shift register (the next-stage first shift register to the i^{th}-stage first shift register) outputs cutoff potential of the (i+a)^{th}-stage scan signal, during a phase when the i^{th}-stage first shift register 10 outputs the turn-on potential of the i^{th}-stage scan signal, the cascade control signal SJL controls the cascade control module 20 between the i^{th}-stage first shift register and the (i+a)^{th}-stage first shift register to be turned off, and the switch control signal SW2 controls the auxiliary cut-off module 30 between the i^{th}-stage first shift register and the (i+a)^{th}-stage first shift register to be turned on. During the control process, the switch states of the other cascade control modules 20 can be the same as or different from that of the cascade control module 20 between the i^{th}-stage first shift register and the (i+a)^{th}-stage first shift register; and the switch states of the other auxiliary cut-off modules 30 can be the same as or different from that of the auxiliary cut-off module 30 between the i^{th}-stage first shift register and the (i+a)^{th}-stage first shift register.

By way of example, suppose that the first scan driving circuit includes n stages of first shift registers 10. During the output process of the 1^{st}-stage to the (i−1)^{th}-stage first shift registers 10, the first cascade control signal SW1 controls the plurality of cascade control modules 20 to be turned on. In the same phase, the switch control signal SW2 controls the auxiliary cut-off modules 30 to be turned off. The 1^{st}-stage to the (i−1)^{th}-stage first shift registers 10 can output the turn-on potential stage by stage, and the 2^{nd}-stage to the i^{th}-stage first shift registers 10 can receive the turn-on potential stage by stage. When the i^{th}-stage first shift register 10 begins to output the turn-on potential, the first cascade control signal SW1 undergoes a potential jump, controlling the plurality of cascade control modules 20 to be turned off, and the switch control signal SW2 also undergoes a potential jump, controlling the auxiliary cut-off modules 30 to be turned on, so that the turn-on potential of the i^{th}-stage scan signal cannot be transmitted to the (i+1)^{th}-stage first shift register 10, and all register input terminals are connected to the auxiliary cut-off signal. Thus, the 1^{st}-stage to the i^{th}-stage first shift registers 10 can output the turn-on potential of the scan signal stage by stage, and the (i+1)^{th}-stage to nth-stage first shift registers 10 can only continuously output the cutoff potential of the scan signal. In this display frame, the partition positions for reduced-frequency display of the display panel are located between two rows of sub-pixels corresponding to the i^{th}-stage and (i+1)^{th}-stage first shift registers 10.

It should be noted that, after the connection between the i^{th}-stage first shift register and the (i+1)^{th}-stage first shift register is cut off, until the end of the current frame of display, even if the first cascade control signal SW1 undergoes a potential jump again, for example, during the scan time of the j^{th} row of sub-pixels, the first cascade control signal SW1 controls the plurality of cascade control modules 20 to be turned on again, and since the (i+1)^{th}-stage to the j^{th}-stage first shift registers 10 will only output the cutoff potential, the j^{th}-stage scan signal cannot provide the turn-on potential to the (j+1)^{th}-stage first shift register 10. As a result, the (j+1)^{th}-stage to the nth-stage first shift registers 10 cannot resume outputting the turn-on potential. In other words, in one frame of display, the display panel has one partition position for reduced-frequency display. However, by combining display frames with different partition positions for reduced-frequency display, a multi-partition, multi-frequency display of the display panel can be achieved. The following provides an illustration using a triple-partition multi-frequency display on a display panel as an example.

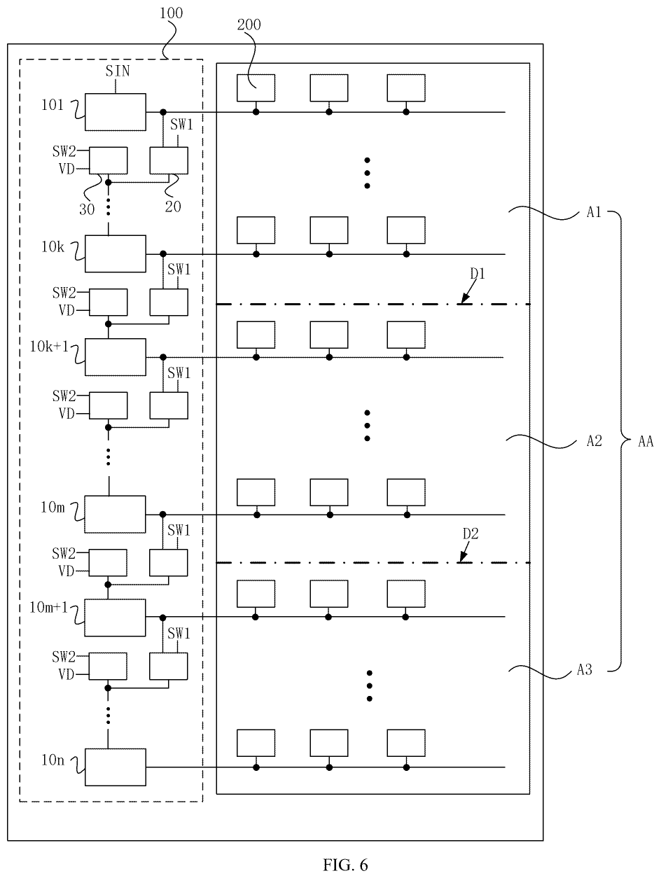

FIG. 6 is a schematic diagram of a structure of a display panel according to an embodiment of the present application. With reference to FIG. 6, by way of example, the first scan driving circuit 100 includes n stages of first shift registers, and the active area AA of the display panel includes n rows of pixel driver circuits 200 (i.e., n rows of sub-pixels), with the i^{th}-stage first shift register correspondingly connected to the i^{th} row of sub-pixels. By way of example, the display panel includes two target partition positions for reduced-frequency display (indicated by dotted lines), including: a first target partition position D1, for example, between the k^{th} row of sub-pixels and the (k+1)^{th} row of sub-pixels; and a second target partition position D2, for example, between the mth row of sub-pixels and the (m+1)^{th} row of sub-pixels. The above two target partition positions divide the active area AA of the display panel into a first sub-active area A1, a second sub-active area A2, and a third sub-active area A3 in the first direction. Along the first direction, the first sub-active area A1 to the third sub-active area A3 display at progressively reduced frequencies. Thus, the display panel may have the following three types of display frames under different display states: a first type of display frame, where each row of sub-pixels in the entire active area AA are in an active frame; a second type of display frame, where, with the first target partition position D1 as the boundary, each row of sub-pixels in the first sub-active area A1 are in an active frames, while each row of sub-pixels in the second sub-active area A2 and the third sub-active area A3 are in an idle frames; a third type of display frame, where, with the second target partition position D2 as the boundary, each row of sub-pixels in the first sub-active area A1 and the second sub-active area A2 are in an active frames, while each row of sub-pixels in the third sub-active area A3 are in an idle frames.

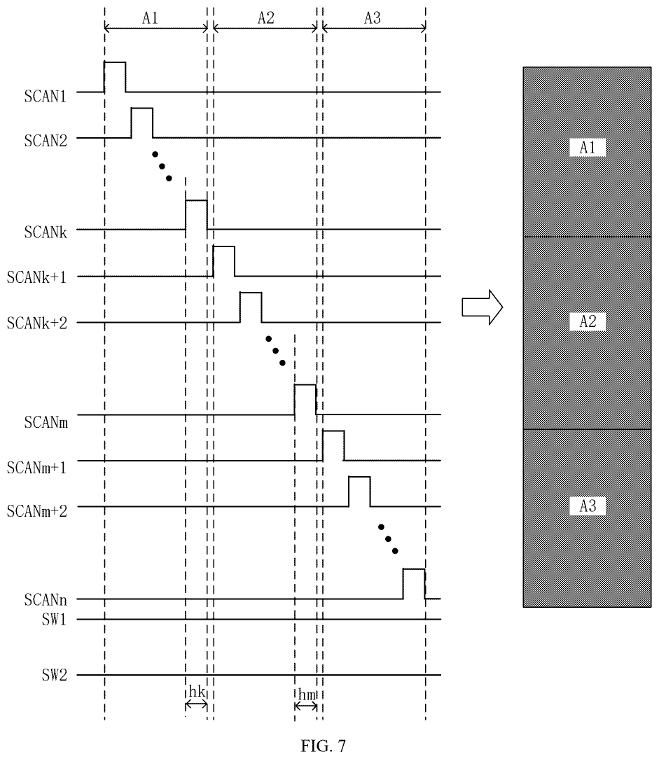

Taking an example in which the turn-on potential of the scan signal is high potential and the plurality of cascade control modules 20 and the auxiliary cut-off modules 30 are both turned on in response to the high potential, the driving processes for the aforementioned three types of display frames will be illustrated below with combined reference to FIGS. 7 to 9, respectively. Here, the transmission time for the turn-on potential of the i^{th}-stage scan signal, i.e., the scan time of the i^{th} row of sub-pixels, is represented by hi. In addition, in FIGS. 7 to 9, by way of example, shade filling is used to indicate that sub-pixels in a sub-active area are in active frames, and blank filling is used to indicate that sub-pixels in a sub-active area are in idle frames.

FIG. 7 is a timing diagram of driving signals for a display frame according to an embodiment of the present application. With reference to FIGS. 6 and 7, this display frame corresponds to a first type of display frame, with each row of sub-pixels in the entire active area AA being in an active frame. The first cascade control signal SW1 remains at high potential, and the switch control signal SW2 remains at low potential. The plurality of cascade control modules 20 remain turned on throughout the display frame, and the auxiliary cut-off modules 30 remain turned off throughout the display frame. The stages of first shift registers remain in a cascaded state throughout the display frame, achieving stage-by-stage transmission of the turn-on potential of the scan signal.

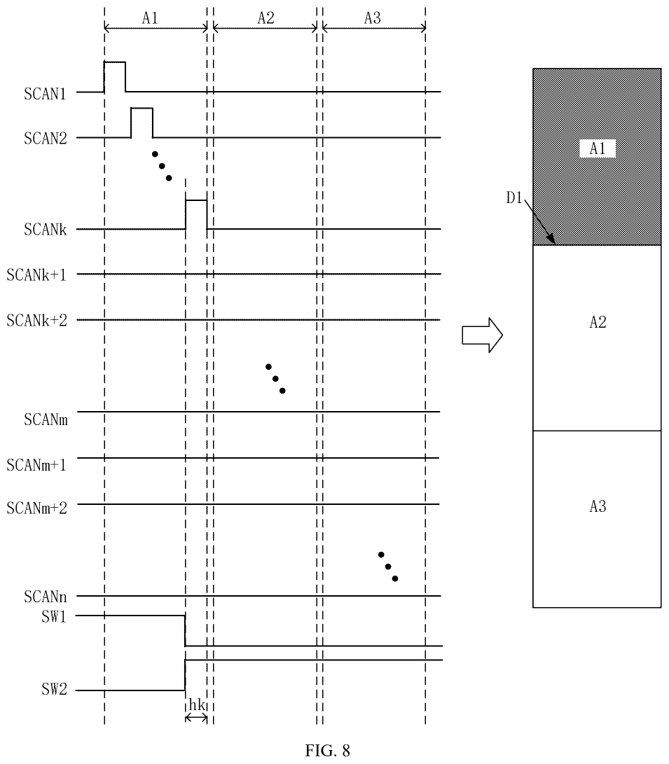

FIG. 8 is a timing diagram of driving signals for another display frame according to an embodiment of the present application. With reference to FIGS. 6 and 8, the display frame corresponds to a second type of display frame, and reduced-frequency display is performed with the first target partition position D1 as the boundary.

Before the scan time hk for the k^{th} row of sub-pixels, the first cascade control signal SW1 remains at high potential, and the switch control signal SW2 remains at low potential, ensuring that the plurality of cascade control modules 20 remain turned on and the auxiliary cut-off modules 30 remain turned off. Shift transmission of the turn-on potential of the scan signal can be achieved between the 1^{st}-stage and the k^{th}-stage first shift registers.

At the beginning of the scan time hk for the k^{th} row of sub-pixels, the first cascade control signal SW1 jumps to low potential, and the switch control signal SW2 jumps to high potential. Until the end of the current frame, the first cascade control signal SW1 remains at low potential, and the switch control signal SW2 remains at high potential. Therefore, from the beginning of the scan time hk for the k^{th} row of sub-pixels until the end of the current frame, the plurality of cascade control modules 20 remain turned off, and the auxiliary cut-off modules 30 remain turned on. For the k^{th}-stage to the n^{th}-stage first shift registers, the connections between adjacent first shift registers are cut off, and the (k+1)^{th}-stage to the n^{th}-stage register input terminals are all connected to the auxiliary cut-off signal VD. The (k+1)^{th}-stage to the n^{th}-stage first shift registers continuously output cutoff potential.

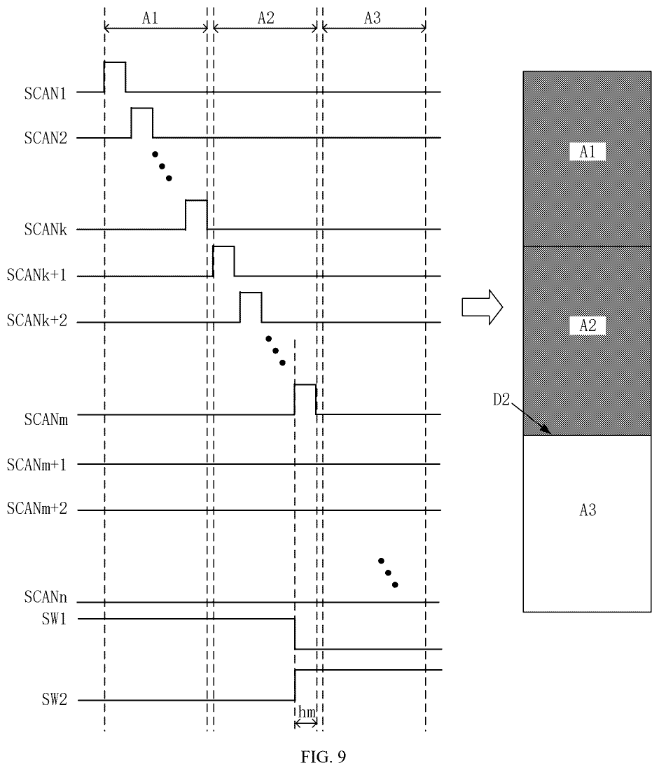

FIG. 9 is a timing diagram of driving signals for a further display frame according to an embodiment of the present application. With reference to FIGS. 6 and 9, the display frame corresponds to a third type of display frame, and reduced-frequency display is performed with the second target partition position D2 as the boundary.

Before the scan time hm for the mth row of sub-pixels, the first cascade control signal SW1 remains at high potential, and the switch control signal SW2 remains at low potential, ensuring that the plurality of cascade control modules 20 remain turned on and the auxiliary cut-off modules 30 remain turned off. Shift transmission of the turn-on potential of the scan signal can be achieved between the 1^{st}-stage and the m^{th}-stage first shift registers.

From the beginning of the scan time hm for the mth row of sub-pixels until the end of the current frame, the first cascade control signal SW1 remains at low potential, and the switch control signal SW2 remains at high potential, ensuring that the plurality of cascade control modules 20 remain turned off, and the auxiliary cut-off modules 30 remain turned on. For the m^{th}-stage to the n^{th}-stage first shift registers, the connections between adjacent first shift registers are cut off, and the (m+1)^{th}-stage to the n^{th}-stage register input terminals are all connected to the auxiliary cut-off signal VD. The (m+1)^{th}-stage to the n^{th}-stage first shift registers continuously output cutoff potential.

In practical applications, by adjusting the order and numbers of the aforementioned three types of display frames, various combinations of partitions and display frequencies can be achieved.

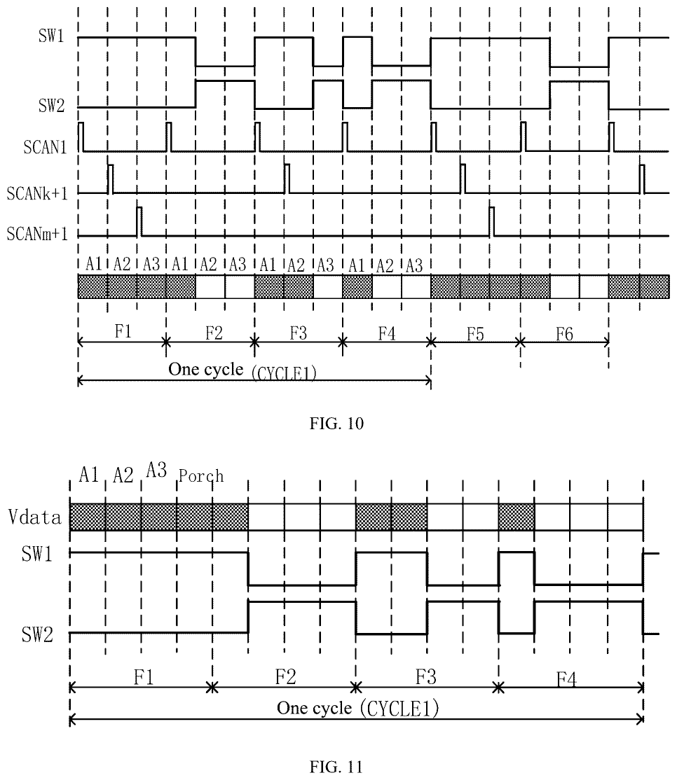

For example, when the first sub-active area A1 displays at a refresh frequency of f, the second sub-active area A2 displays at a refresh frequency of f/2, and the third sub-active area A3 displays at a refresh frequency of f/4, the combination method of each type of display frame is as shown in FIG. 10. With reference to FIG. 10, for each row of sub-pixels in the first sub-active area A1, the display frames can be active frames. FIG. 10 shows the waveform of the 1^{st}-stage scan signal SCAN1. It can be seen that in each frame of display, the 1^{st}-stage scan signal SCAN1 includes a turn-on pulse. For each row of sub-pixels in the second sub-active area A2, odd-numbered frames can be set as active frames, and even-numbered frames can be set as idle frames. FIG. 10 exemplarily shows the waveform of the (k+1)^{th}-stage scan signal SCANk+1. It can be seen that the (k+1)^{th}-stage scan signal SCANk+1 includes a turn-on pulse only in odd-numbered frames. For each row of sub-pixels in the third sub-active area A3, 3 idle frames can be provided between two adjacent active frames. FIG. 10 exemplarily shows the waveform of the (m+1)^{th}-stage scan signal SCANm+1. It can be seen that the (m+1)^{th}-stage scan signal SCANm+1 includes a turn-on pulse in display frame F1 and display frame F5, that is, it includes a turn-on pulse only in the (4i+1)^{th} display frame, while maintaining cutoff potential in the other display frames. Taking the four display frames F1 to F4 as one cycle (CYCLE1), by repeating the driving process within this cycle, stable partitioned multi-frequency display can be implemented, with the first sub-active area A1 displaying at a refresh frequency of f, the second sub-active area A2 displaying at a refresh frequency of f/2, and the third sub-active area A3 displaying at a refresh frequency of f/4. Among them, display frame F1 corresponds to the first type of display frame, display frames F2 and F4 correspond to the second type of display frame, and display frame F3 corresponds to the third type of display frame.

When it is necessary to adjust the partition positions between the sub-active areas, this can be achieved by adjusting the potential jump time of the first cascade control signal SW1 and the switch control signal SW2 in each type of display frame. For example, by adjusting the potential jump moments of the first cascade control signal SW1 and the switch control signal SW2 forward in FIG. 8, the first target partition position D1 can be moved upward.

When it is necessary to adjust the refresh frequencies of the sub-active areas, this can be achieved by controlling the order and numbers of the various types of display frame in different cycles. For example, by adding a plurality of display frames identical to display frame F2 between display frame F1 and display frame F3 in FIG. 10, the refresh frequencies of both the second sub-active area A2 and the third sub-active area A3 can be reduced.

By using different cycles for display in different time periods, a display scheme with dynamically adjustable refresh frequencies can be achieved.

During the scanning process of each row of sub-pixels, the data voltage on the data line can be controlled to update or switch accordingly based on the refresh states of each row of sub-pixels. Specifically, for sub-pixel rows in an active frame, the data voltage needs to be updated, and within the duration of the turn-on potential of the scan signal for that row, the data voltage is normally transmitted to each sub-pixel in that row through the data line. For sub-pixel rows in an idle frame, the data voltage stops being output to the sub-pixels. When the data voltage stops being output, the state thereof can be set to maintain high potential, maintain low potential, maintain the data voltage from the previous row, or remain at a potential value corresponding to any grayscale level. Maintaining fixed potential for the data voltage during idle frames can reduce the power consumption of the panel. In practical applications, the state of the data voltage can follow the changes of the first cascade control signal SW1. When the first cascade control signal SW1 controls the plurality of cascade control modules 20 to be turned on, the data voltage is updated. When the first cascade control signal SW1 controls the plurality of cascade control modules 20 to be turned off, the data voltage stops being output.

In practical applications, considering the inherent porch phase after each row of sub-pixels have been completely scanned, a driving timing sequence of the display panel can be as shown in FIG. 11. During each frame of display, after the scan time of the three sub-active areas has all ended, the duration of the current display frame continues until the porch phase ends, after which the next display frame begins. Since no sub-pixels are scanned during the porch phase, that is, the potential of the scan signals corresponding to all sub-pixel rows in the active area remains at the cutoff potential during the porch phase, the potential of the first cascade control signal SW1 and the switch control signal SW2 can be set arbitrarily, such as maintaining the potential from the previous phase, so as to reduce the number of potential jumps, thereby simplifying the control logic.

The aforementioned implementations illustrate the functional modes of the plurality of cascade control modules 20 and the auxiliary cut-off modules 30 during the display process. The specific structures of the plurality of cascade control modules 20 and the auxiliary cut-off modules 30 will be described below.

With continued reference to FIG. 5, in an implementation, in one embodiment, each auxiliary cut-off module 30 includes: a fourth transistor T4, where a gate of the fourth transistor T4 is connected to the switch control signal SW2, a first electrode of the fourth transistor T4 is connected to the auxiliary cut-off signal, and a second electrode of the fourth transistor T4 is electrically connected to a second electrode of the corresponding first transistor T1. In this embodiment, the auxiliary cut-off module 30 is configured to include a single transistor, making the structure of the auxiliary cut-off module 30 simple and easy to implement.

With continued reference to FIG. 5, in an implementation, in one embodiment, the display panel is provided with: a first clock signal line for transmitting a first clock signal CLK1; a second clock signal line for transmitting a second clock signal CLK2; a first potential signal line for transmitting a first potential signal VGH; a second potential signal line for transmitting a second potential signal VGL; a first cascade control signal line for transmitting the first cascade control signal SW1; and a switch control signal line for transmitting the switch control signal SW2. All stages of first shift register 10 are connected to the second potential signal VGL and the first potential signal VGH; and the first clock terminal and the second clock terminal of two adjacent stages of first shift registers 10 are alternately electrically connected to the first clock signal line and the second clock signal line, respectively. By way of example, the first potential signal VGH may be high potential signal, and the second potential signal VGL may be low potential signal. The potential of the first potential signal VGH or the second potential signal VGL serves as the turn-on potential of the scan signal, while the other serves as the cutoff potential.

In one embodiment, the potential signal serving as the cutoff potential may be reused as an auxiliary cut-off signal to reduce the wiring of the display panel. For example, as shown in FIG. 5, when the turn-on potential of the scan signal is high potential, the second potential signal VGL may be reused as the auxiliary cut-off signal, and the first electrode of the fourth transistor T4 is electrically connected to the second potential signal line. Alternatively, when the turn-on potential of the scan signal is low potential, the first potential signal VGH may be reused as the auxiliary cut-off signal, and the first electrode of the fourth transistor T4 is electrically connected to the first potential signal line.

With continued reference to FIG. 5, in an implementation, in one embodiment, each cascade control module 20 includes: a first transistor T1, where a gate of the first transistor T1 is connected to the first cascade control signal SW1, a first electrode of the first transistor T1 is electrically connected to a current-stage register output terminal 12, and a second electrode of the first transistor T1 is electrically connected to a next-stage register input terminal 11. In this embodiment, the cascade control module 20 is configured to include a single transistor, making the structure of the cascade control module 20 simple and easy to implement.

On the basis of the aforementioned implementations, in one embodiment, the first transistor T1 has the same channel type as that of the fourth transistor T4, and the two transistors can be fabricated in the same process to simplify the panel fabrication process. On this basis, the first cascade control signal SW1 and the switch control signal SW2 can be configured as inverted signals, with the jump time of the two control signals being consistent. This ensures that when the cascade control module 20 is turned off, the auxiliary cut-off module 30 can be reliably turned on, transmitting the auxiliary cut-off signal to the next-stage register input terminal 11.

By way of example, as shown in FIG. 5, both the first transistor T1 and the fourth transistor T4 are N-type transistors. For example, the first transistor T1 and the fourth transistor T4 include metal-oxide-semiconductor transistors. Compared to polysilicon transistors, N-type metal-oxide-semiconductor transistors can provide better cut-off effects.

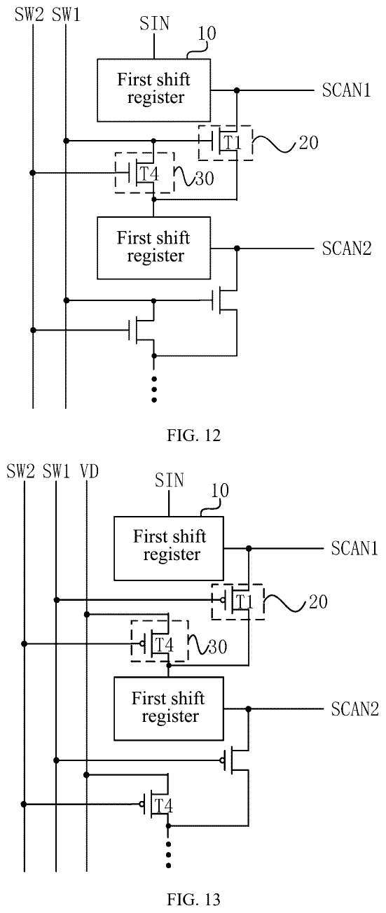

FIG. 12 is a schematic diagram of a structure of a further display driver circuit according to an embodiment of the present application. With reference to FIG. 12, in an implementation, in one embodiment, when the first transistor T1 has the same channel type as that of the fourth transistor T4, and the turn-on potential of the fourth transistor T4 is the same as that of the scan signal, the first cascade control signal SW1 can be reused as the auxiliary cut-off signal to simplify the circuit structure. Since the switch control signal SW2 controls the fourth transistor T4 to be turned on, the first cascade control signal SW1, as the inverted signal for the switch control signal SW2, remains at the cutoff potential of the fourth transistor T4, which is equivalent to remaining at the cutoff potential of the scan signal. By using the switch control signal SW2 as the input signal of the fourth transistor T4, the normal operation of the auxiliary cut-off module 30 can be ensured.

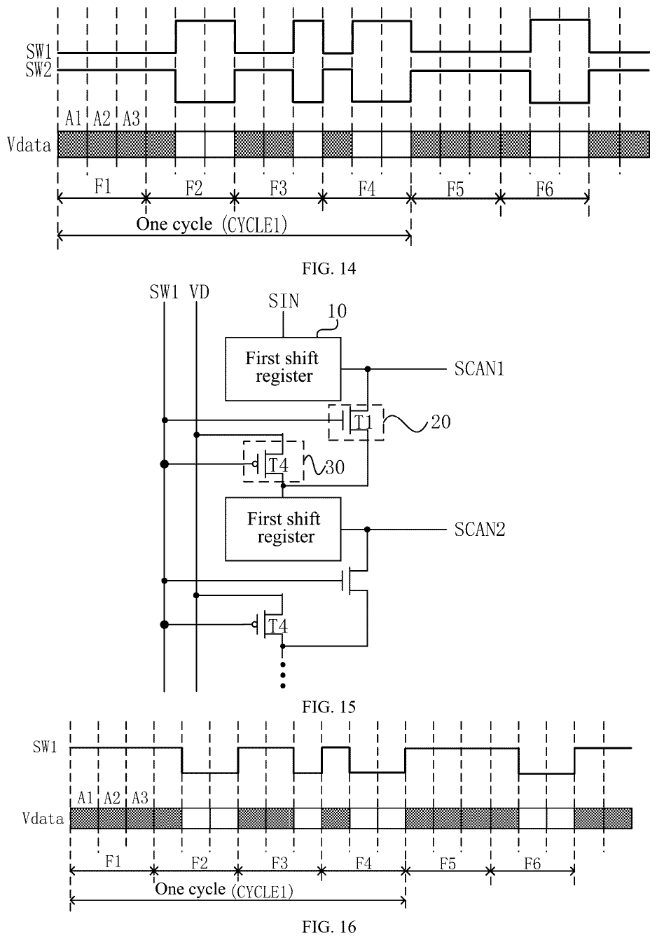

FIG. 13 is a schematic diagram of a structure of a further display driver circuit according to an embodiment of the present application. With reference to FIG. 13, in an implementation, in one embodiment, both the first transistor T1 and the fourth transistor T4 can be P-type transistors. Since the first shift register 10 is typically composed of P-type transistors, this configuration can allow the first transistor T1 and the fourth transistor T4 to be fabricated in the same process as the transistors in the first shift register 10, thereby simplifying the panel fabrication process. In this case, for the driving timing sequence of the display panel, reference can be made to FIG. 14. Compared to FIG. 10, since the turn-on potential of each transistor in this embodiment is low potential, all switch control signals are converted to inverted signals for the corresponding switch control signals in FIG. 10. For the changes in the switch states of the functional modules, reference can still be made to the previously described explanation of the driving process of the display panel, which will not be repeated here.

FIG. 15 is a schematic diagram of a structure of a further display driver circuit according to an embodiment of the present application. With reference to FIG. 15, in an implementation, in one embodiment, the first transistor T1 has a different channel type from that of the fourth transistor T4. The first cascade control signal SW1 can be reused as the switch control signal SW2 to reduce the number of signal lines required by the display panel and simplify the wiring of the display panel. In this case, for the driving timing sequence of the display panel, reference can be made to FIG. 16. Compared to FIG. 10, since in this embodiment, the turn-on potential of the first transistor T1 is in an opposite phase to that of the turn-on potential of the fourth transistor T4, and the switch states of the two transistors are opposite in practical applications, the two transistors can be controlled by the same switch control signal. For the changes in the switch states of the functional modules, reference can still be made to the previously described explanation of the driving process of the display panel, which will not be repeated here.

The aforementioned implementations, in some embodiments, illustrate adjustment schemes for the partition positions for reduced-frequency display of the display panel under the unified control mode of the plurality of cascade control modules, but they are not intended to limit the present application. In other implementations, in one embodiment, the plurality of cascade control modules 20 may have other structures. By controlling the cascade control module 20 at a preset position to remain in an off state during each frame of display, the cascade control signal achieves the adjustment of the partition positions for reduced-frequency display of the display panel.

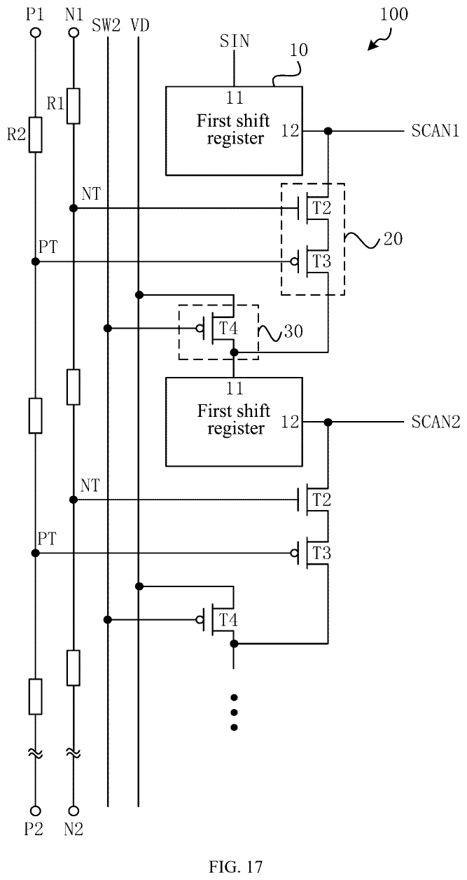

FIG. 17 is a schematic diagram of a structure of a further display driver circuit according to an embodiment of the present application. With reference to FIG. 17, in an implementation, in one embodiment, the first scan driving circuit 100 further includes: a first power terminal N1 and a second power terminal N2, where the first power terminal N1 is disposed at the far end of the driver IC, that is, proximate to the end of the 1^{st}-stage first shift register; and the second power terminal N2 is disposed at the near end of the driver IC, that is, proximate to the end of the last-stage first shift register. Additionally, the first scan driving circuit 100 further includes: a first resistor string, where the first resistor string includes a plurality of first resistors R1 connected in series between the first power terminal N1 and the second power terminal N2, with a plurality of first output terminals NT tapped from the first resistor string, where the plurality of first output terminals NT output the second cascade control signals. The plurality of first output terminals NT are respectively connected to the plurality of cascade control modules 20, and at least one first resistor R1 is disposed between two adjacent ones of the plurality of first output terminals NT.

When the potential provided to the first power terminal N1 and the second power terminal N2 is the same, all second cascade control signals have the same potential. By setting the first power terminal N1 and the second power terminal N2 to have different potential, the second cascade control signals can be made have different potential.

Correspondingly, the cascade control module 20 includes: a second transistor T2, where a gate of the second transistor T2 is connected to a corresponding one of the second cascade control signals, and the second transistor T2 is connected between a corresponding current-stage register output terminal 12 and a corresponding next-stage register input terminal 11. For example, the first electrode of the second transistor T2 is electrically connected to the corresponding current-stage register output terminal 12, and the second electrode of the second transistor T2 is electrically connected to the corresponding next-stage register input terminal 11. By way of example, along the direction from the first power terminal N1 to the second power terminal N2, a plurality of first output terminals NT are sequentially electrically connected to the gates of the 1^{st} to the last second transistors T2.

By adjusting the potential of the first power terminal N1 and the second power terminal N2, the potential values of the second cascade control signals can be adjusted, thereby controlling the on/off of the second transistors T2. In one frame of display, by setting the potential of the above two power terminals, the second transistors T2 above the partition position can be controlled to remain turned on during the display frame, and the second transistors T2 below the partition position can be controlled to remain turned off during the display frame, thereby achieving multi-frequency display.

For the embodiment shown in FIG. 17, when it is necessary for part of the second transistors T2 to be turned on and part of the second transistors T2 to be turned off, at the boundary position between the turned-on and turned-off parts, part of the second transistors T2 may be in a weakly on state, rendering the switch states thereof insufficiently stable. To address the above situation, the inventors provide an improved embodiment, which will be explained below.

With continued reference to FIG. 17, on the basis of the aforementioned implementations, in one embodiment, the first scan driving circuit 100 further includes: a third power terminal P1 and a fourth power terminal P2. The third power terminal P1 is arranged at the far end of the driver IC, and the fourth power terminal P2 is arranged at the near end of the driver IC.

Additionally, the first scan driving circuit 100 further includes: a second resistor string. The second resistor string includes a plurality of second resistors R2 connected in series between the third power terminal P1 and the fourth power terminal P2, with a plurality of second output terminals PT tapped from the second resistor string, where the plurality of second output terminals PT output the third cascade control signals; and the plurality of second output terminals PT are respectively connected to the plurality of cascade control modules 20, and at least one second resistor R2 is disposed between two adjacent ones of the plurality of second output terminals PT. The cascade control signals include the second cascade control signals and the third cascade control signals. When the potential provided to the third power terminal P1 and the fourth power terminal P2 is the same, all third cascade control signals have the same potential. By setting the third power terminal P1 and the fourth power terminal P2 to have different potential, the third cascade control signals can be made have different potential.

Correspondingly, each cascade control module 20 further includes: a third transistor T3, a gate of the third transistor T3 being connected to a corresponding one of the third cascade control signals, and the third transistor T3 and the corresponding second transistor T2 being connected in series between a corresponding current-stage register output terminal 12 and a corresponding next-stage register input terminal 11. For example, the first electrode of the third transistor T3 is electrically connected to the second electrode of the corresponding second transistor T2, and the second electrode of the third transistor T3 is electrically connected to the corresponding next-stage register input terminal 11. Specifically, along the direction from the third power terminal P1 to the fourth power terminal P2, a plurality of second output terminals PT are sequentially electrically connected to the gates of the 1^{st} to the last third transistors T3.

In summary, by adjusting the potential of the first power terminal N1 and the second power terminal N2, the potential values of the second cascade control signals can be adjusted, thereby controlling the on/off of the second transistors T2. By adjusting the potential of the third power terminal P1 and the fourth power terminal P2, the potential values of the third cascade control signals can be adjusted, thereby controlling the on/off of the third transistors T3. In one frame of display, when it is necessary for part of the second transistors T2 to be turned on and part of the second transistors T2 to be turned off, the third transistors T3 corresponding to the second transistors T2 in a weakly on state are also set to be in a weakly on state, enabling an overlap to achieve a stable switch state. This ensures a clear boundary between the turn-on and cut-off of the cascade control module 20, thereby clarifying the display partition position of the display panel in the first direction.

In summary, by setting the potential of the aforementioned four power terminals during one frame of display, the second transistors T2 and third transistors T3 above the partition position can be controlled to remain turned on during the display frame, and the second transistors T2 and third transistors T3 below the partition position can be controlled to remain turned off during the display frame, thereby achieving multi-frequency display.

By way of example, the resistance values of each first resistor R1 and each second resistor R2 are identical. One first resistor R1 is interposed between two adjacent first output terminals NT, and one second resistor R2 is interposed between two adjacent second output terminals PT, facilitating the determination of the potential values of the control signals. By way of example, the resistors can be implemented using on-panel traces.

By way of example, as shown in FIG. 17, the second transistor T2 has a different channel type from that of the third transistor T3. For example, the second transistor T2 is an N-type transistor, and the third transistor T3 is a P-type transistor. The control process of the cascade control module 20 with this structure is as follows.

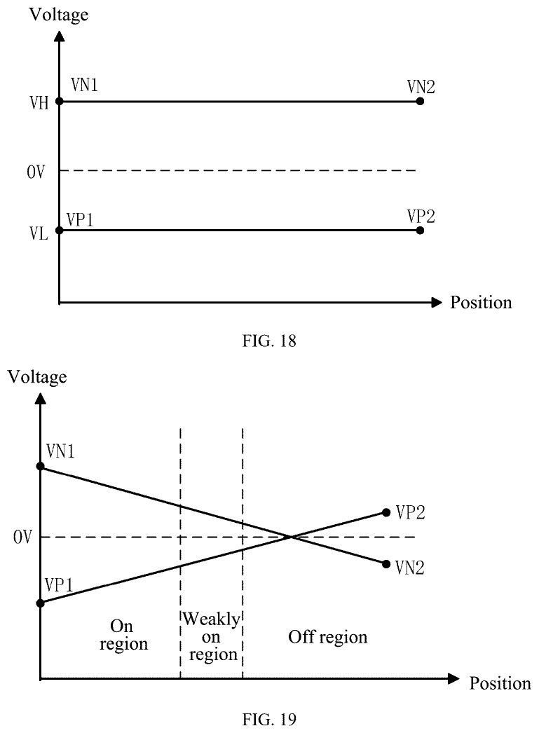

FIG. 18 is a schematic diagram of a power terminal voltage setting mode according to an embodiment of the present application. This mode corresponds to the state in which display is performed at the same refresh rate at full-screen positions of the display panel. As shown in FIG. 18, the potential VN1 of the first power terminal and the potential VN2 of the second power terminal remain at the same high potential VH, and all of the plurality of first output terminals NT are at the same high potential, ensuring that all of the second transistors T2 are turned on. The potential VP1 of the third power terminal and the potential VP2 of the fourth power terminal remain at the same low potential VL, and all of the plurality of second output terminals PT are at the same low potential, ensuring that all of the third transistors T3 are turned on. During this display frame, the switch control signal SW2 remains high, causing all of the fourth transistors T4 to remain turned off, so that the stages of first shift registers 10 can normally perform stage-by-stage transmission.

FIG. 19 is a schematic diagram of another power terminal voltage setting mode according to an embodiment of the present application, which corresponds to the state in which display is performed at a high refresh rate on the upper half of the display panel and at a low refresh rate on the lower half. As shown in FIG. 19, the potential VN1 of the first power terminal is set to a higher potential greater than 0 V, and the potential VN2 of the second power terminal is set to potential less than 0 V. With the voltage division of the first resistor string, the potential of the plurality of first output terminals N1 gradually decreases from the far end of the IC to the near end of the IC, causing the on states of the second transistors T2 to exhibit a trend of an on region, a weakly on region, and an off region from the far end of the IC to the near end of the IC. Additionally, the potential VP1 of the third power terminal is set to potential with a relatively large absolute value that is less than 0 V, and the potential VP2 of the fourth power terminal is set to potential greater than 0 V. The potential of the second control terminals PT gradually increases from the far end of the IC to the near end of the IC, causing the on states of the third transistors T3 to exhibit a trend of an on region, a weakly on region, and an off region from the far end of the IC to the near end of the IC. By adjusting the potential of the power terminals, the boundary positions of the states of the second transistor T2 and the third transistor T3 can be controlled to be the same. The weakly on states of the second transistor T2 and the third transistor T3 can overlap to enable the cascade control module 20 as a whole to exhibit a stable switch state. Thus, by controlling the potential of the four power terminals, the positions where the plurality of cascade control modules 20 start to be turned off can be precisely controlled, thereby controlling the partition positions for reduced-frequency display on the display panel. During the scan time of a high-frequency display region, the switch control signal SW2 is at high potential, controlling the fourth transistor T4 to be turned off, thereby enabling the first shift registers in this region to implement normal stage-by-stage transmission of the scan signal. During the scan time of a low-frequency display region, the switch control signal SW2 is at low potential, causing the fourth transistor T4 to be turned on, so that the auxiliary cut-off signal VD is transmitted to the next-stage first shift register 10 to interrupt the stage-by-stage transmission of the scan signal.

The aforementioned embodiments provide a driving scheme for the first scan driving circuit to perform partitioned multi-frequency display on the display panel. The applicable scenarios of the first scan driving circuit are described below when the turn-on pulse output by the first shift register has different potential levels.

In one embodiment, the turn-on potential of the scan signal output by the first shift register is low potential. At this time, the auxiliary cut-off signal is at high potential. The following provides illustrations of the structure of the pixel driver circuit that applies such a scan signal, the shift register circuit that generates such a scan signal, and the connection method between the pixel driver circuit and the first scan driving circuit.

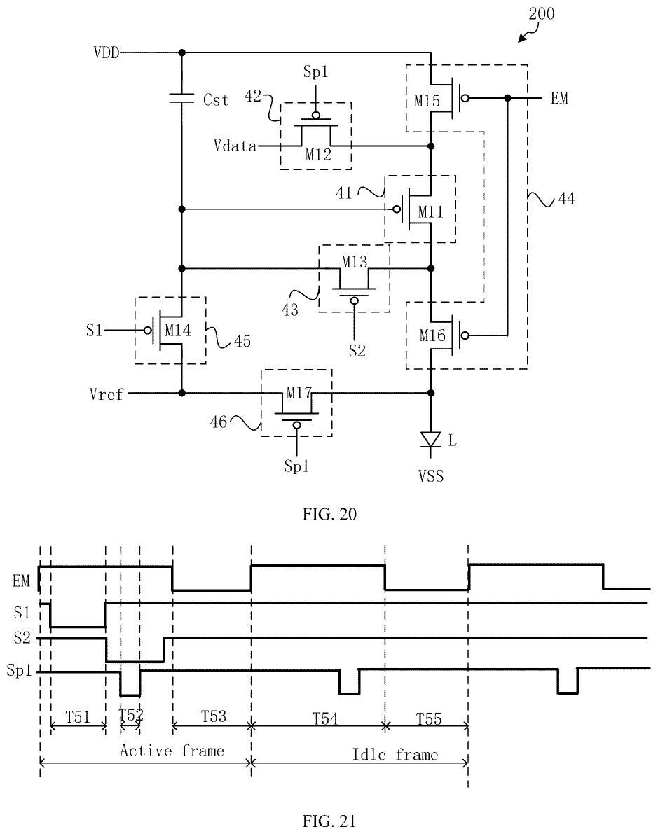

FIG. 20 is a schematic diagram of a structure of a pixel driver circuit according to an embodiment of the present application. With reference to FIG. 20, in one embodiment, the pixel driver circuit 200 includes: a driving module 41, a data writing module 42, a threshold compensation module 43, and a light emission control module 44. The driving module 41, the light emission control module 44, and the light-emitting device L are connected in series, the data writing module 42 is electrically connected to the first terminal of the driving module 41, and the threshold compensation module 43 is connected between the control terminal and the second terminal of the driving module 41. The control terminal of the data writing module 42 is connected to a third control signal Sp1, the control terminal of the threshold compensation module 43 is connected to a second control signal S2, and the control terminal of the light emission control module 44 is connected to a light emission control signal EM. Additionally, the pixel driver circuit 200 may further include a first reset module 45 electrically connected to the control terminal of the driving module 41; a second reset module 46 electrically connected to the anode of the light-emitting device L; and a storage capacitor Cst electrically connected to the control terminal of the driving module 41. The control terminal of the first reset module 45 is connected to a first control signal S1, and the control terminal of the second reset module 46 is connected to the third control signal Sp1.

By way of example, the driving module 41 includes a driving transistor M11, the data writing module 42 includes a transistor M12, the threshold compensation module 43 includes a transistor M13, the light emission control module 44 includes transistors M15 and M16, the first reset module 45 includes a transistor M14, and the second reset module 46 includes a transistor M17, constituting a pixel driver circuit including seven transistors and one capacitor. The gates of the transistors serve as the control terminals of the respective functional modules. By way of example, all of the transistors may be P-type transistors, fabricated using low temperature poly-silicon (LTPS) technology, constituting an LTPS pixel driver circuit.

FIG. 21 is a schematic diagram of a driving timing sequence of a pixel driver circuit according to an embodiment of the present application. With combined reference to FIGS. 20 and 21, the driving process of this pixel driver circuit 200 includes the following phases.

Initialization phase T51: The first control signal S1 is at low potential, while the third control signal Sp1, the second control signal S2, and the light emission control signal EM are at high potential. The transistor M14 is turned on, and the initialization voltage signal Vref is transmitted to the gate of the driving transistor M11 through the transistor M14, initializing the gate of the driving transistor M11.

Data writing phase T52: The third control signal Sp1 and the second control signal S2 are at low potential, while the first control signal S1 and the light emission control signal EM are at high potential. Both the transistors M12 and M13 are turned on. The data voltage Vdata is transmitted to the gate of the driving transistor M11 via the transistors M12, the driving transistor M11, and the transistor M13, until the gate voltage of the driving transistor M11 reaches Vdata+Vth1, at which point the driving transistor M11 is turned off. Here, Vth1 is the threshold voltage of the driving transistor M11. Meanwhile, the transistor M17 is turned on, and the initialization voltage signal Vref is transmitted to the anode of the light-emitting device L through the transistor M17, initializing the anode of the light-emitting device L.

First light emission phase T53: The light emission control signal EM is at low potential, while the first control signal S1, the third control signal Sp1, and the second control signal S2 are at high potential. Both the transistors M15 and M16 are turned on. The driving transistor M11 generates a driving current based on the first power signal VDD and the gate potential of the driving transistor M11, driving the light-emitting device L to emit light.

The aforementioned driving process represents a driving timing sequence of the pixel driver circuit 200 in an active frame. When the driving process of the pixel driver circuit 200 further includes an idle frame, the driving process in the idle frame includes the following phases.

Non-light emission phase T54: The light emission control signal EM is at high potential. Both the transistors M15 and M16 are turned off. The connection path between the driving transistor M11 and the light-emitting device L is disconnected, and the light-emitting device L does not emit light. During this phase, the turn-on pulse of the third control signal Sp1 may be present, enabling the resetting of the anode of the light-emitting device L and the first electrode of the driving transistor M11 to correct the characteristic drift of the light-emitting device L and the driving transistor M11 during the light emission process.

Second light emission phase T55: The light emission control signal EM is at low potential. Both the transistors M15 and M16 are turned on. The driving transistor M11 generates a driving current based on the first power signal VDD and the potential of the gate of the driving transistor M11 that is saved during the active frame, driving the light-emitting device L to emit light.

As can be seen from the above analysis, when the pixel driver circuit 200 is displaying at a high frequency, the first control signal S1, the third control signal Sp1, the second control signal S2, and the light emission control signal EM are all high-frequency signals. When the pixel driver circuit 200 is displaying at a low frequency, the first control signal S1 and the second control signal S2 are low-frequency signals, the light emission control signal EM is a high-frequency signal, and the third control signal Sp1 can be either a low-frequency signal or a high-frequency signal.

The first scan driving circuit according to the embodiments of the present application is used to control the data writing process of each pixel driver circuit. The scan signal output by each stage of first shift register can serve as the second control signal S2 required in the pixel driver circuit to control the process of writing the data voltage to the gate of the driving transistor M11. Other control signals required by the pixel driver circuit can be separately provided by other scan driving circuits in the display panel. For example, the display driver circuit may further include: a second scan driving circuit for providing the third control signal Sp1 to each row of pixel driver circuits; a light emission control driving circuit for providing the light emission control signal EM to each row of pixel driver circuits; and a third scan driving circuit for providing the first control signal S1 to each row of pixel driver circuits. Among these, since the frequency of the first control signal S1 varies with the display refresh frequency, the third scan driving circuit can adopt the same structure as the first scan driving circuit. Further, since the first control signal S1 and the second control signal S2 have the same turn-on potential and turn-on pulse width, as well as frequency, and for the same row of sub- pixels, the only difference between the two control signals lies in the duration during which the turn-on potential is applied, in the display driver circuit, the first scan driving circuit can be reused as the third scan driving circuit to reduce the size of the panel bezel. Specifically, different stages of first shift registers can be connected to the same row of pixel driver circuits, where the preceding stage of first shift register provides the first control signal S1 to the pixel driver circuit, while the subsequent stage (the next one stage or the next several stages, which can be set based on actual requirements) of first shift register provides the second control signal S2 to the pixel driver circuit.

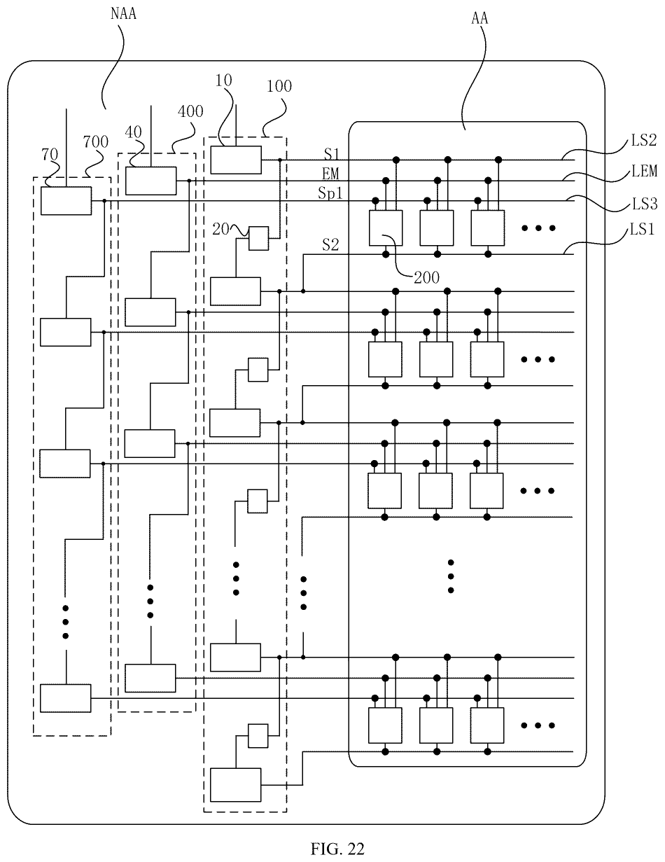

FIG. 22 is a schematic diagram of a structure of another display panel according to an embodiment of the present application. Below, in combination with FIG. 22, the connection relationship that the first scan driving circuit may have with the pixel driver circuit when it is applied to the display panel will be described. With reference to FIG. 22, in one embodiment, in the display panel, the pixel driver circuits 200 are arranged in the active area AA of the display panel, and the scan driving circuits and the light emission control driving circuits 400 are arranged in the non-active area NAA of the display panel. The driving circuits in the non-active area NAA provide control signals to the rows of pixel driver circuits 200 through signal lines.

Specifically, the display panel is provided with a first scan driving circuit 100, a second scan driving circuit 700, and a light emission control driving circuit 400. The second scan driving circuit 700 includes a plurality of stages of second shift registers 70 arranged in cascade; and the light emission control driving circuit 400 includes a plurality of stages of third shift registers 40 arranged in cascade. The register output terminal of the j^{th}-stage first shift register 10 is electrically connected to the second scan line LS2 connected to the j^{th} row of pixel driver circuits 200, and the register output terminal of the (j+b)^{th}-stage first shift register 10 is electrically connected to the first scan line LS1 connected to the j^{th} row of pixel driver circuits 200. Here, j and b are both positive integers, and in FIG. 22, b=1, for example. The j^{th}-stage second shift register 70 is electrically connected to the third scan line LS3 connected to the j^{th} row of pixel driver circuits 200, and the j^{th}-stage third shift register 40 is electrically connected to the light emission control signal line LEM connected to the j^{th} row of pixel driver circuits 200. The first scan lines LS1 respectively provide the second control signal S2 to each row of pixel driver circuits 200, the second scan lines LS2 respectively provide the first control signal S1 to each row of pixel driver circuits 200, the third scan lines LS3 respectively provide the third control signal Sp1 to each row of pixel driver circuits 200, and the light emission control signal lines LEM respectively provide the light emission control signal EM to each row of pixel driver circuits 200.

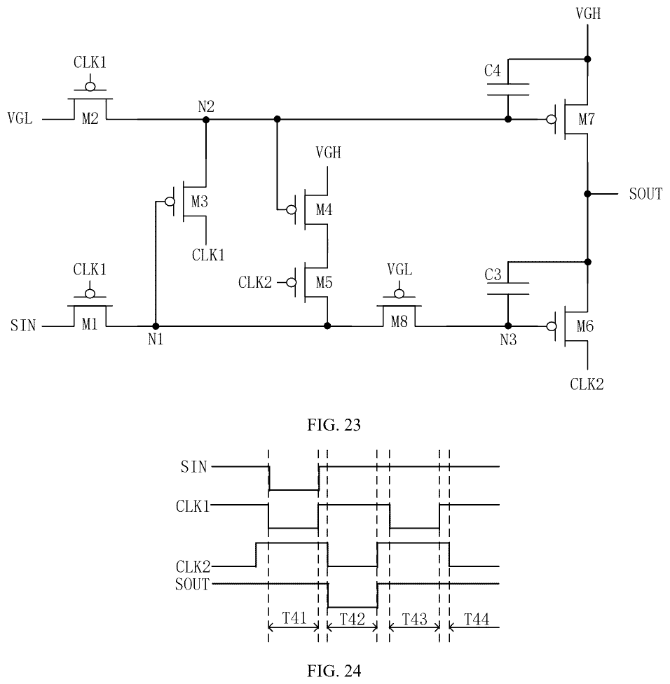

FIG. 23 is a schematic diagram of a structure of a first shift register according to an embodiment of the present application. With reference to FIG. 23, in one embodiment, the first shift register may adopt a circuit architecture including eight transistors and two capacitors. The first shift register includes: transistors M1 to M8, and capacitors C3 and C4. FIG. 24 is a schematic diagram of a driving timing sequence of a first shift register according to an embodiment of the present application. With reference to FIGS. 23 and 24, the driving process of this shift register includes the following phases.

First phase T41: The first clock signal CLK1 and the scan input signal SIN are at low potential, while the second clock signal CLK2 is at high potential. The transistors M1 and M2 are turned on, and the transistor M5 is cut off; the transistor M8 is turned on; the low potential of the scan input signal SIN is transmitted through the transistor M1 to the node N1, causing the transistor M3 to be turned on; the low potential of the first clock signal CLK1 is transmitted through the transistor M3 to the node N2, and at the same time, the low potential of the second potential signal VGL is transmitted through the transistor M2 to the node N2, causing the transistor M7 to be turned on; the high potential of the first potential signal VGH is transmitted through the transistor M7 to the output terminal of the shift register; the low potential of the node N1 is transmitted through the transistor M8 to the node N3, causing transistor M6 to be turned on; and the high potential of the second clock signal CLK2 is transmitted through the transistor M6 to the output terminal of the shift register. As a result, in the first phase T41, the output signal SOUT of the shift register is at high potential.

Second phase T42: The second clock signal CLK2 is at low potential, while the first clock signal CLK1 and the scan input signal SIN are both at high potential. The transistors M1 and M2 are cut off, and the transistor M5 is turned on; and the transistor M8 remains turned on. Due to the storage effect of the capacitor C3, the node N3 remains at the low potential from the previous phase, causing the transistor M6 to be turned on; and the low potential of the node N3 is transmitted through the transistor M8 to the node N1, causing transistor M3 to be turned on. The high potential of the first clock signal CLK1 is transmitted through the transistor M3 to the node N2, causing the transistor M7 to be cut off. The low potential of the second clock signal CLK2 is output through the transistor M6, and the output signal SOUT is at low potential.

Third phase T43: The first clock signal CLK1 is at low potential, while the second clock signal CLK2 and the scan input signal SIN are both at high potential. The transistors M1 and M2 are turned on, and the transistor M5 is cut off; and the transistor M8 is turned on. The high potential of the scan input signal SIN is transmitted through the transistor M1 to the node N1, causing the transistor M3 to be cut off; and the high potential of the node N1 is transmitted through the transistor M8 to the node N3, causing the transistor M6 to be cut off. The low potential of the second potential signal VGL is transmitted through the transistor M2 to the node N2, causing the transistor M7 to be turned on; and the high potential of the first potential signal VGH is output through the transistor M7, and the output signal SOUT is at high potential.

Fourth phase T44: The second clock signal CLK2 is at low potential, while the first clock signal CLK1 and the scan input signal SIN are both at high potential. The transistors M1 and M2 are cut off, and the transistor M5 is turned on; and the transistor M8 is turned on. Due to the storage effect of the capacitor C4, the node N2 remains at the low potential from the previous phase, causing the transistors M4 and M7 to be turned on. The high potential of the first potential signal VGH is transmitted through the transistors M4, M5, and M8 to the node N3, causing the transistor M6 to be cut off. the high potential of the first potential signal VGH is output through the transistor M7, and the output signal SOUT is at high potential.

By repeating the third phase T43 and the fourth phase T44, the output signal SOUT remains at high potential until the scan input signal SIN becomes low potential again.

In one embodiment, the turn-on potential of the scan signal output by the first shift register is high potential. At this time, the auxiliary cut-off signal is at low potential. The following provides illustrations of the structure of the pixel driver circuit that applies such a scan signal, the shift register circuit that generates such a scan signal, and the connection method between the pixel driver circuit and the first scan driving circuit.

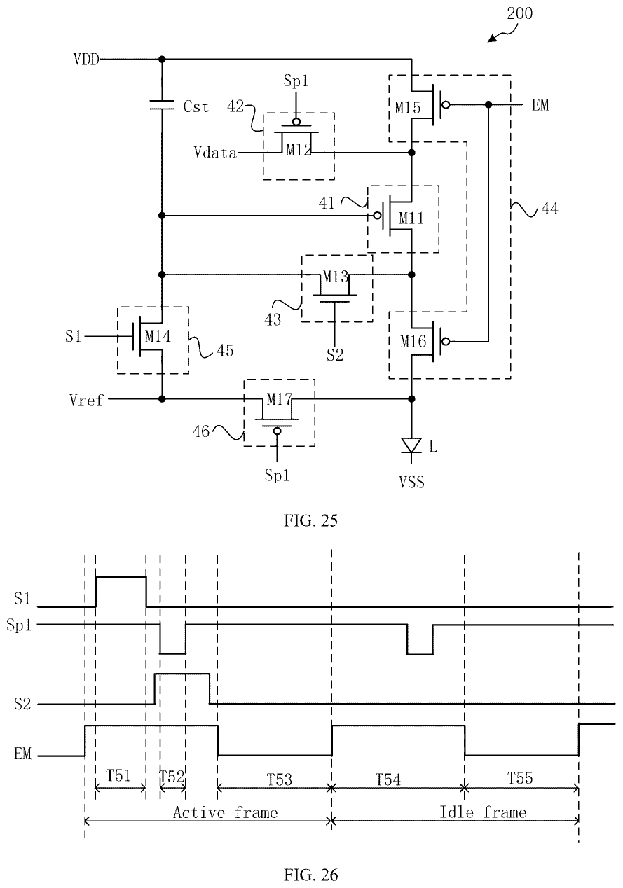

FIG. 25 is a schematic diagram of a structure of another pixel driver circuit according to an embodiment of the present application. The difference from the pixel driver circuit in FIG. 20 is that, in FIG. 25, the transistor M13 in the threshold compensation module 43 and the transistor M14 in the first reset module 45 are replaced with N-type transistors, such as IGZO transistors, constituting a low temperature polycrystalline oxide (LTPO) pixel driver circuit. Based on the advantages of low leakage current and good long-range uniformity of the N-type IGZO transistors, this pixel driver circuit can suppress current leakage at the gate of the driving transistor M11 during the light emission process, which is beneficial for achieving display at lower refresh frequencies.

FIG. 26 is a schematic diagram of a driving timing sequence of another pixel driver circuit according to an embodiment of the present application. FIG. 26 differs from FIG. 21 only in that both the first control signal S1 and the second control signal S2 are changed to the inverted signals for the corresponding control signals in FIG. 21, that is, the turn-on potential of both the first control signal S1 and the second control signal S2 is high potential. The above analysis of the driving process for the pixel driver circuit also applies to this pixel driver circuit and will not be repeated. Furthermore, this pixel driver circuit can still adopt the same connection relationship with the scan driving circuits as that shown in FIG. 22, which will not be repeated.

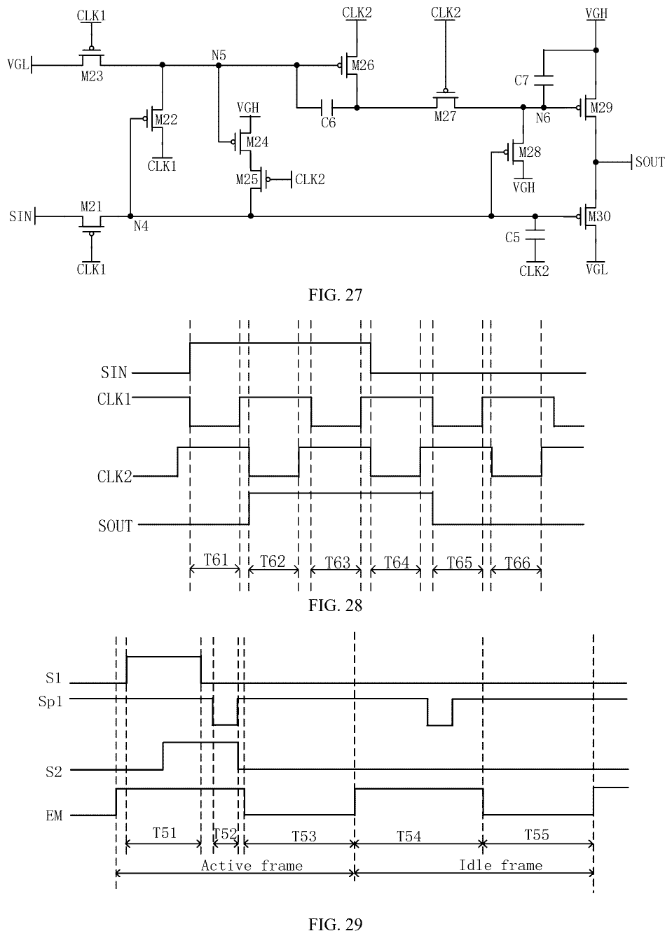

FIG. 27 is a schematic diagram of a structure of another first shift register according to an embodiment of the present application. With reference to FIG. 27, in one embodiment, the first shift register may adopt a circuit architecture including ten transistors and three capacitors to generate an output signal of which the turn-on potential is high potential. The first shift register includes: transistors M21 to M30, and capacitors C5 to C7. FIG. 28 is a schematic diagram of a driving timing sequence of another first shift register according to an embodiment of the present application. With reference to FIGS. 27 and 28, the driving process of this shift register includes the following phases.

First phase T61: The first clock signal CLK1 is at low potential, while the second clock signal CLK2 and the scan input signal SIN are at high potential. The transistors M21 and M23 are turned on, and the transistors M25 and M27 are cut off; and the high potential of the scan input signal SIN is transmitted through the transistor M21 to the node N4, causing the transistors M22, M28, and M30 to be cut off. The low potential of the second potential signal VGL is transmitted through the transistor M23 to the node N5, causing the transistors M24 and M26 to be turned on. Due to the storage effect of the capacitor C7, the node N6 maintains the high potential from the previous phase, causing the transistor M29 to be cut off. As a result, the output signal SOUT remains at the low potential from the previous phase.

Second phase T62: The second clock signal CLK2 is at low potential, while the first clock signal CLK1 and the scan input signal SIN are at high potential. The transistors M25 and M27 are turned on, and the transistors M21 and M23 are cut off. Due to the storage effect of the capacitor C6, the node N5 remains at the low potential from the previous phase, causing the transistors M24 and M26 to be turned on. The high potential of the first potential signal VGH is transmitted through the transistors M24 and M25 to the node N4, causing the transistors M22, M28, and M30 to remain the cutoff state. The low potential of the second clock signal CLK2 is transmitted through the transistors M26 and M27 to the node N6, causing the transistor M29 to be turned on. The first potential signal VGH is transmitted through the transistor M29, causing the output signal SOUT to become high potential.

Third phase T63: The first clock signal CLK1 is at low potential, while the second clock signal CLK2 and the scan input signal SIN are at high potential. The transistors M21 and M23 are turned on, and the transistors M25 and M27 are cut off. the high potential of the scan input signal SIN is transmitted through the transistor M21 to the node N4, causing the transistors M22, M28, and M30 to be cut off. The low potential of the second potential signal VGL is transmitted through the transistor M23 to the node N5, causing the transistors M24 and M26 to be turned on. Due to the storage effect of the capacitor C7, the node N6 maintains the low potential from the previous phase, causing the transistor M29 to remain turned on and the output signal SOUT to remain at high potential.

Fourth phase T64: The first clock signal CLK1 is at high potential, while the second clock signal CLK2 and the scan input signal SIN are at low potential. The transistors M21 and M23 are cut off, and the transistors M25 and M27 are turned on. Due to the storage effect of the capacitor C6, the node N5 remains at the low potential from the previous phase, causing the transistors M24 and M26 to be turned on. The high potential of the first potential signal VGH is transmitted through the transistors M24 and M25 to the node N4, causing the transistors M22, M28, and M30 to remain the cutoff state. The low potential of the second clock signal CLK2 is transmitted through the transistors M26 and M27 to the node N6, causing the transistor M29 to be turned on. The high potential of the first potential signal VGH is transmitted through the transistor M29, causing the output signal SOUT to remain at high potential.

Fifth phase T65: The second clock signal CLK2 is at high potential, while the first clock signal CLK1 and the scan input signal SIN are at low potential. The transistors M21 and M23 are turned on, and the transistors M25 and M27 are cut off. The low potential of the scan input signal SIN is transmitted through the transistor M21 to the node N4, causing the transistors M22, M28, and M30 to be turned on. The low potential of the first clock signal CLK1 is transmitted through the transistor M22 to the node N5, causing the transistors M24 and M26 to be turned on. However, due to the cutoff of the transistor M27, the low potential of the node N5 cannot be transmitted to the node N6. The high potential of the first potential signal VGH is transmitted through the transistor M28 to the node N6, causing the transistor M29 to be cut off. The low potential of the second potential signal VGL is transmitted through the transistor M30, causing the output signal SOUT to become low potential.

Sixth phase T66: The first clock signal CLK1 is at high potential, while the second clock signal CLK2 and the scan input signal SIN are at low potential. The transistors M25 and M27 are turned on. Due to the coupling effect of the capacitor C5, as the second clock signal CLK2 becomes low potential, the potential of the node N4 changes to low potential lower than that in the fifth phase 65, causing the transistors M22, M28, and M30 to remain turned on; the high potential of the first clock signal CLK1 is transmitted through the transistor M22 to the node N5, causing the node N5 to become high potential; and the high potential of the first potential signal VGH is transmitted through the transistor M28 to the node N6, causing the transistor M29 to remain cut off. Compared to the previous phase, although the transistor M27 has been turned on in this phase, since the potential of the node N5 has become high potential, the transistor M26 is turned off and will not pull down the potential of the node N6, so that the node N6 can maintain high potential. The low potential of the second potential signal VGL is transmitted through the transistor M30, causing the output signal SOUT to remain low potential.

Subsequently, the fifth phase T25 and the sixth phase T26 are repeated, and the shift register continuously outputs low potential. This continues until the scan input signal SIN becomes high potential again.

It should be noted that, in the shift register circuit according to this embodiment, by adjusting the cutoff pulse width of the scan input signal SIN, the correspondence between the scan input signal SIN and the output signal SOUT can be adjusted. An exemplary illustration is provided below for application scenarios of different pulse widths.

In one embodiment, by controlling the cutoff pulse width of the input signal SIN to be the same as the turn-on pulse width of the first clock signal CLK1, the cutoff pulses of the scan input signal SIN and the output signal SOUT can be made non-overlapping. Thus, the scan driving circuits and the pixel driver circuits can adopt the connection method as shown in FIG. 22, and the scan driving circuits can provide the driving waveforms shown in FIG. 26 to the pixel driver circuits.

In one embodiment, when the cutoff pulse width of the scan input signal SIN contains a plurality of turn-on pulses of the first clock signal CLK1, the cutoff pulses of the scan input signal SIN and the output signal SOUT overlap. As shown in FIG. 28, when the cutoff pulse width of the scan input signal SIN contains two turn-on pulses of the first clock signal CLK1, in order to provide the driving waveform shown in FIG. 26 to the pixel driver circuit, the output signal of the j^{th}-stage first shift register may be used as the first control signal S1 for the j^{th} row of pixel driver circuits, and the output signal of the (j+3)^{th}-stage first shift register may be used as the second control signal S2 for the j^{th} row of pixel driver circuits.

In one embodiment, the case where the cutoff pulses of the scan input signal SIN and the output signal SOUT overlap shown in FIG. 28 is also applicable to the connection method as shown in FIG. 22. In this case, a driving timing sequence provided by the scan driving circuits to the pixel circuits is as shown in FIG. 29. Unlike in FIG. 26, in FIG. 29, the turn-on pulses of the first control signal S1 and the second control signal S2 overlap. With combined reference to FIGS. 25 and 29, during the overlap of the turn-on pulses of the first control signal S1 and the second control signal S2, both the transistors M13 and M14 are turned on. After being transmitted through the transistor M14 to the gate of the driving transistor M11, the initialization voltage signal Vref continues to be transmitted through the transistor M13 to the second electrode of the driving transistor M11, thereby achieving initialization of the second electrode of the driving transistor M11 and improving the initialization effect. In addition, the data writing phase T52 is still performed after the initialization phase T51 ends, that is, the turn-on pulse of the third control signal Sp1 is located after the end of the turn-on pulse of the first control signal S1 and overlaps with the turn-on pulse of the second control signal S2.

It should be noted that the structures of the shift registers according to the aforementioned embodiments are not intended to limit the present application. In other implementations, the first shift register may be implemented using the existing shift register circuits with any structure.

The aforementioned implementations exemplarily provide a scheme for partitioned multi-frequency driving of the display panel in the first direction, that is, upper-lower partitioned multi-frequency driving, but this is not intended to limit the present application. In other implementations, by adding a split-screen control module in the active area, the display panel can also support split-screen driving in the second direction (i.e., the sub-pixel row direction), that is, left and right partitioned multi-frequency driving, to achieve more flexible control of the display panel. Here, the first direction and the second direction intersect.

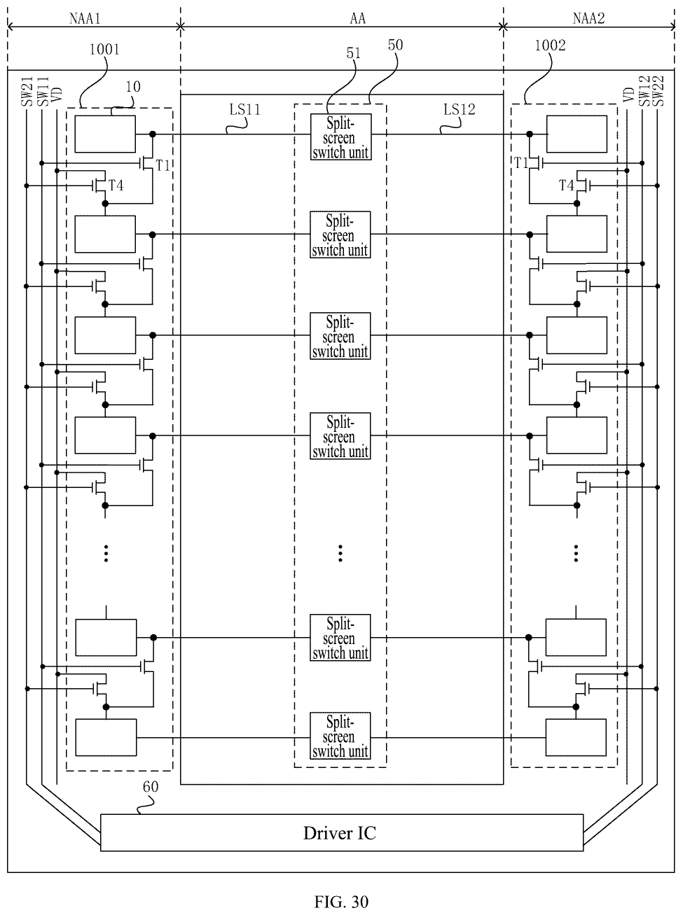

FIG. 30 is a schematic diagram of a structure of a further display panel according to an embodiment of the present application. With reference to FIG. 30, in one embodiment, the non-active area of the display panel includes two non-active sub-areas NAA1 and NAA2, where the two non-active sub-areas NAA1 and NAA2 are arranged on both sides of the active area AA along the second direction. At least one first scan driving circuit includes two first scan driving circuits 1001 and 1002. By way of example, the first-side first scan driving circuit 1001 is arranged in the first non-active sub-area NAA1, and the second-side first scan driving circuit 1002 is arranged in the second non-active sub-area NAA2. The corresponding stages of first shift registers 10 in the first-side first scan driving circuit 1001 and the second-side first scan driving circuit 1002 are connected to the same first scan line.

Among all of the first scan lines in the display panel, each first scan line in at least part of the first scan lines includes at least two sub-scan lines. The display driver circuit further includes: at least one split-screen control module 50, where the split-screen control module 50 is disposed in the active area AA; and each split-screen control module 50 may include a plurality of split-screen switch units 51, the plurality of split-screen switch units 51 within the same split-screen control module 50 correspond to the first scan lines composed of sub-scan lines, respectively. Each split-screen switch unit 51 is connected between two adjacent sub-scan lines LS11 and LS12 in the same first scan line. When any split-screen switch unit 51 is turned off in response to the split-screen control signal, the first-side first scan driving circuit 1001 and the second-side first scan driving circuit 1002 transmit scan signals to the sub-scan lines on both sides of the split-screen switch unit 51, respectively.

In a case where a plurality of split-screen switch units 51 are included on the same scan line, the plurality of split-screen switch units 51 on the same scan line are arranged sequentially along the second direction. At the same moment, the number of split-screen switch units on the same first scan line that are in an off state is less than or equal to one. The turned-off split-screen switch unit 51 divides the first scan line into two parts, and the sub-scan lines on both sides are driven by different first scan driving circuits to transmit scan signals to ensure the normal driving of the sub-pixels on both sides.

In one embodiment, a cascade control signal connected to the first-side first scan driving circuit 1001 is a first-side cascade control signal, and a cascade control signal connected to the second-side first scan driving circuit 1002 is a second-side cascade control signal, the first-side cascade control signal being different from the second-side cascade control signal. In addition, a switch control signal connected to the first-side first scan driving circuit 1001 is a first-side switch control signal SW21, and a switch control signal connected to the second-side first scan driving circuit 1002 is a second-side switch control signal SW22, the first-side switch control signal SW21 being different from the second-side switch control signal SW22. In this way, when the split-screen control module 50 is turned off, the sub-active areas on both sides of the split-screen control module 50 can display at at least one of different refresh frequencies and at different upper-lower partition positions. The control signals connected to the first scan driving circuits 1001 and 1002 on both sides can be separately provided by the driver IC 60.

Here, the operational process of the split-screen control module 50 includes the following.

When the sub-pixels in the same row have the same refresh frequency, all of the plurality of split-screen switch units 51 corresponding to that row of sub-pixels are controlled to be turned on, and the scan signals output by the first shift registers 10 on both the left and right sides are connected together, achieving dual-side driving for that row of sub-pixels to enhance the driving capability of the scan driving circuit. This mitigates display non-uniformity at the split-screen position caused by RC delay during single-side driving and avoids the risk of displaying split-screen boundaries, that is, avoiding the phenomenon of brightness differences between the left and right half-screens. In a case where the full-screen refresh frequency is the same, all of the plurality of split-screen switch units 51 can be controlled to be turned on.

When the refresh frequencies on the left and right sides of a row of sub-pixels are different, upon the arrival of the turn-on pulse of the scan signal for that row of sub-pixels, the split-screen switch unit 51 for the left-right split-screen position corresponding to that row of sub-pixels is controlled to be turned off, and the other split-screen switch units for that row are controlled to be turned on. The scan signal on the left side of the split-screen position is provided by the 1^{st} first scan driving circuit 1001, and the scan signal on the right side of the split-screen position is provided by the 2^{nd} first scan driving circuit 1002, enabling a driving method with different refresh rates for the left and right screens.

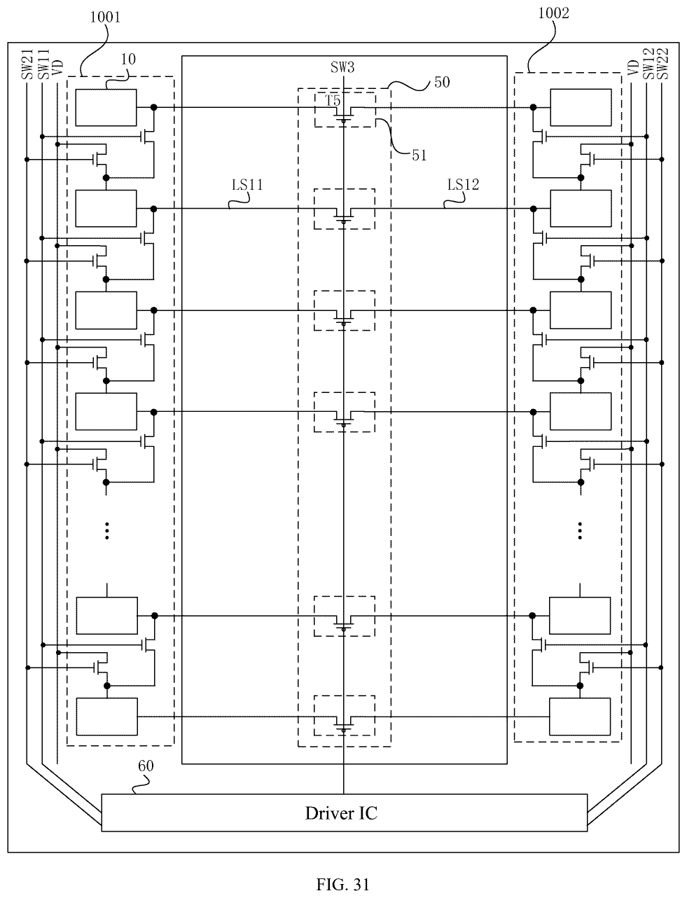

FIG. 31 is a schematic diagram of a structure of a further display panel according to an embodiment of the present application. With reference to FIG. 31, on the basis of the aforementioned implementations, in one embodiment, all of the plurality of split-screen switch units 51 in the same split-screen control module 50 are connected to the same split-screen control signal SW3. By way of example, different split-screen control modules 50 are connected to different split-screen control signals; and at the same time, at most one split-screen control module 50 is turned off, while the other split-screen control modules 50 are turned on. The split-screen control signal SW3 can be provided by the driver IC 60. During one frame of display, the split-screen control signal SW3 may undergo a potential jump or may not undergo a potential jump. When the split-screen control signal SW3 does not undergo a potential jump during one frame of display, the left-right split-screen state of the display panel remains unchanged during that frame of display; and when the split-screen control signal SW3 undergoes a potential jump during one frame of display, the left-right split-screen state of the display panel changes during that frame of display, for example, having left-right split-screens for a period of time and no left-right split-screens for the other periods of time. The driving mode of the display panel is illustrated below taking an example where the display driver circuit includes one split-screen control module 50. It should be noted that when the positions where the plurality of split-screen switch units 51 are disposed are determined, the left-right split-screen positions of the display panel are fixed. In the following implementations, solid lines are used to indicate fixed-position split-screens, and dashed lines are used to indicate adjustable-position split-screens.

With continued reference to FIG. 31, in one embodiment, the first scan line includes a first sub-scan line LS11 and a second sub-scan line LS12, with the first sub-scan line LS11 and the second sub-scan line LS12 being connected to different first scan driving circuits, respectively. The display driver circuit includes one split-screen control module 50; and each of the plurality of split-screen switch units 51 is separately electrically connected to a corresponding first sub-scan line LS11 and second sub-scan line LS12. The first-side first scan driving circuit 1001 is connected to the first-side first cascade control signal SW11 and the first-side switch control signal SW21, and the second-side first scan driving circuit 1002 is connected to the second-side first cascade control signal SW12 and the second-side switch control signal SW22. Based on this structure, the display panel can be flexibly controlled to use single-side driving or dual-side driving in different scenario modes. The display modes are separately illustrated below taking an example where the split-screen switch unit is turned on in response to low potential, and the cascade control module and the auxiliary cut-off module are turned on in response to high potential.

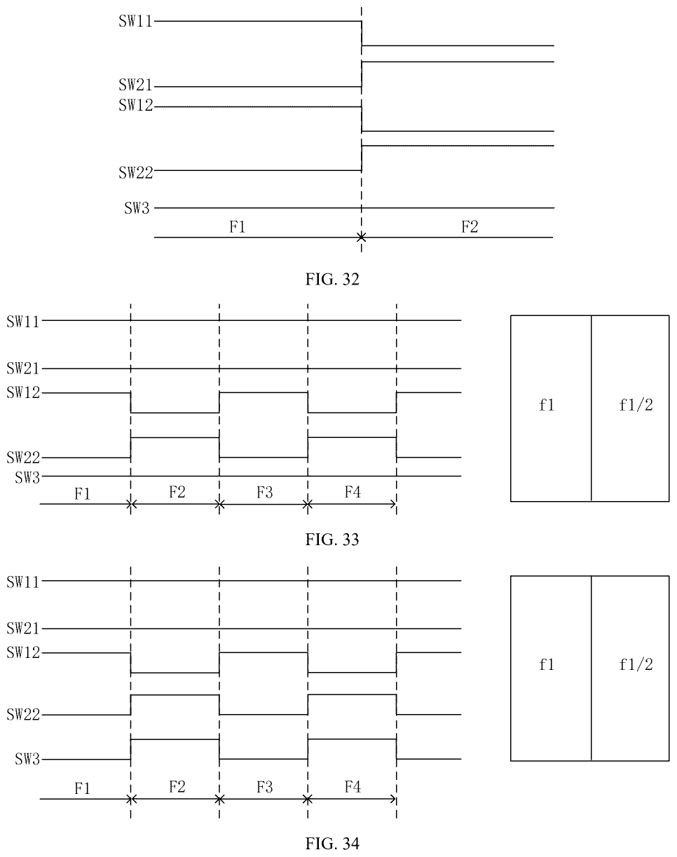

FIG. 32 is a schematic diagram of a driving timing sequence of a further display panel according to an embodiment of the present application, which corresponds to a display mode with a unified full-screen refresh frequency for the display panel. In this mode, the split-screen control signal SW3 remains at low potential, controlling all of the plurality of split-screen switch units 51 to remain turned on, thereby achieving dual-side driving of the entire display panel. At this time, the output states of the first scan driving modules on both sides remain consistent. In the display frame F1, corresponding to a full-screen active frame, the first cascade control signals SW11 and SW12 remain at high potential, and the switch control signals SW21 and SW22 remain at low potential, enabling both the first scan driving circuits to achieve stage-by-stage shifting output of the turn-on potential of the scan signal. When low-frequency refresh is performed in full screen, the display frame further includes an idle frame, as shown in the display frame F2. In this case, the first cascade control signals SW11 and SW12 remain at low potential, the switch control signals SW21 and SW22 remain at high potential, and the scan input signals connected to the two first scan driving circuits can remain at cutoff potential, causing the stage-by-stage transmissions of both first scan driving circuits to be interrupted, with all scan signals remaining at the cutoff potential.

FIG. 33 is a schematic diagram of a driving timing sequence of a further display panel according to an embodiment of the present application, which corresponds to a display mode in which the display panel is partitioned only in the second direction, i.e., left-right split-screen multi-frequency display. In this mode, the split-screen control signal SW3 remains at high potential, controlling all of the plurality of split-screen switch units 51 to remain turned off, thereby achieving single-side driving for each of the left-side and right-side sub-active areas. In this case, the 1^{st} first scan driving circuit 1001 provides scan signals based on the driving requirements of the left-side sub-active area, and the 2^{nd} first scan driving circuit 1002 provides scan signals based on the driving requirements of the right-side sub-active area. By way of example, the left-side sub-active area displays at a refresh frequency of f1, and the right-side sub-active area displays at a refresh frequency of f1/2. For instance, the first-side first cascade control signal SW11 can remain at high potential, while the first-side switch control signal SW21 can remain at low potential, controlling the left-side sub-active area to refresh in each display frame. The second-side first cascade control signal SW12 remains at high potential during odd-numbered frames and at low potential during even-numbered frames, while the second-side switch control signal SW22 remains at low potential during odd-numbered frames and at high potential during even-numbered frames, controlling the right-side sub-active area to refresh only during odd-numbered frames.

The potential settings of the split-screen control signal SW3 described above are not intended to limit the present application. In other implementations, when turn-on potential of scan signals is simultaneously transmitted on two sub-scan lines respectively connected to both ends of one split-screen switch unit among the plurality of split-screen switch units on the same first scan line, the split-screen control signal can control the split-screen switch unit to be turned on. Taking the structure in FIG. 31 as an example, during the scan time of any row of pixel driver circuits, when the pixel driver circuits on both sides of a split-screen switch unit perform data writing simultaneously, the split-screen control signal SW3 can transition to turn-on potential, controlling the split-screen switch unit to be turned on, thereby achieving dual-side driving for that row of pixel driver circuits during the scan time of that row of pixel driver circuits to enhance the data writing effects. By way of example, as shown in FIG. 34, during display frames F1 and F3, both the left-side and right-side sub-active areas are refreshed, and the split-screen control signal SW3 can be set to low potential accordingly.

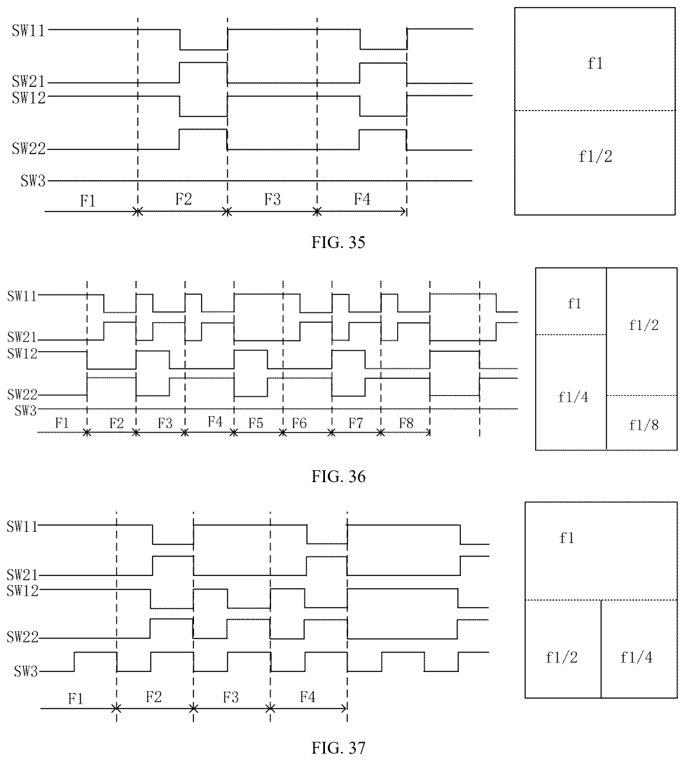

FIG. 35 is a schematic diagram of a driving timing sequence of a further display panel according to an embodiment of the present application, which corresponds to a display mode in which the display panel performs multi-frequency display only in the first direction, i.e., upper-lower split-screen multi-frequency display. In this mode, the split-screen control signal SW3 remains at low potential, controlling all of the plurality of split-screen switch units 51 to remain turned on, thereby achieving dual-side driving of the entire display panel. At this time, the output states of the first scan driving modules on both sides remain consistent. By way of example, the upper-side sub-active area displays at a refresh frequency of f1, and the lower-side sub-active area displays at a refresh frequency of f1/2. For example, in the display frame F1, the first cascade control signals SW11 and SW12 remain at high potential, and the switch control signals SW21 and SW22 remain at low potential, controlling all sub-pixels in the active area to be refreshed. In the display frame F2, before the arrival of the scan time of the previous row of sub-pixels at the target partition position, the first cascade control signals SW11 and SW12 remain at high potential, and the switch control signals SW21 and SW22 remain at low potential, controlling all sub-pixels in the upper-side sub-active area to be refreshed; and from the arrival of the scan time of the previous row of sub-pixels at the target partition position until the end of the current frame, the first cascade control signals SW11 and SW12 remain at low potential, and the switch control signals SW21 and SW22 remain at high potential, controlling all sub-pixels in the lower-side sub-active area not to be refreshed. Taking the display frame F1 and the display frame F2 as one cycle, by repeating this cycle, each sub-pixel in the upper-side sub-active area is refreshed in every display frame, while each sub-pixel in the lower-side sub-active area is refreshed only in odd-numbered frames.

FIG. 36 is a schematic diagram of a driving timing sequence of a further display panel according to an embodiment of the present application, which corresponds to a display mode in which the display panel performs multi-frequency display in both the first direction and the second direction, for example, upper-lower-left-right quad-split-screen multi-frequency display. In this mode, the split-screen control signal SW3 can always remain at high potential, controlling all of the plurality of split-screen switch units 51 to remain turned off, thereby achieving single-side driving for each of the left-side and right-side sub-active areas, so as to reduce potential jumps of the split-screen control signal SW3 and simplify the control logic. Alternatively, in any display frame, when part of the rows of pixel driver circuits on both the left and right sides are refreshed, the split-screen control signal SW3 can be set to remain at low potential during the scan time of the corresponding row of pixel driver circuits. By way of example, the upper-left sub-active area displays at a refresh frequency of f1, the lower-left sub-active area displays at a refresh frequency of f1/4, the upper-right sub-active area displays at a refresh frequency of f1/2, and the lower-right sub-active area displays at a refresh frequency of f1/8. For the two sub-active areas on the left side, the driving mode of the 1^{st} first scan driving circuit 1001 takes 4 display frames as one cycle. Through the first-side first cascade control signal SW11 and first-side switch control signal SW21, the sub-pixels in the upper-left-side sub-active area are controlled to refresh in every display frame, while the sub-pixels in the lower-left-side sub-active area are controlled to refresh only in the first display frame of each cycle. For the two sub-active areas on the right side, the driving mode of the 2^{nd} first scan driving circuit 1002 takes 8 display frames as one cycle. Through the second-side first cascade control signal SW12 and second-side switch control signal SW22, the sub-pixels in the upper-right-side sub-active area are controlled to refresh in odd-numbered frames, while the sub-pixels in the lower-right-side sub-active area are controlled to refresh only in the first display frame of each cycle.

FIG. 37 is a schematic diagram of a driving timing sequence of a further display panel according to an embodiment of the present application, which corresponds to a display mode in which the display panel performs multi-frequency display in both the first direction and the second direction, for example, triple-split-screen multi-frequency display with no left-right split-screen on the upper side and left-right split-screens on the lower side. In this mode, during each frame of display, the split-screen control signal SW3 undergoes a potential jump, with the potential jump time coordinated with the potential jump time of the first cascade control signal and the switch control signal. By way of example, the upper-side sub-active area displays at a refresh frequency of f1, the lower-left sub-active area displays at a refresh frequency of f1/2, and the lower-right sub-active area displays at a refresh frequency of f1/4. During the scan time of the upper-side sub-active area, the split-screen control signal SW3 remains at low potential, controlling all of the plurality of split-screen switch units 51 to remain turned on, thereby achieving dual-side driving of the upper-side sub-active area. During the driving process of the upper-side sub-active area, the outputs of two first scan driving circuits remain consistent, for example, controlling the upper-side sub-active area to refresh in every display frame. During the scan time of the lower-side two sub-active areas, the split-screen control signal SW3 remains at high potential, controlling all of the plurality of split-screen switch units 51 to remain turned off, thereby achieving single-side driving for each of the lower-left and lower-right two sub-active areas. During the driving process of the lower-side two sub-active areas, through the first-side first cascade control signal SW11 and the first-side switch control signal SW21, the sub-pixels in the lower-left-side sub-active area are controlled to refresh in odd-numbered frames, and through the second-side first cascade control signal SW12 and the second-side switch control signal SW22, the sub-pixels in the lower-right-side sub-active area are controlled to refresh once every 4 display frames.

By way of example, this display mode with no split-screens in the left-right sub-active areas on the upper side can also be implemented by controlling the upper-left and upper-right two sub-active areas to have consistent refresh frequencies in the quad-split-screen mode. However, as shown in FIG. 37, when the left-side and right-side sub-active areas have consistent refresh frequencies, controlling the plurality of split-screen switch units to be turned on can mitigate display non-uniformity caused by single-side driving, thereby improving display effects of the upper-side sub-active area. Additionally, in the driving mode shown in FIG. 37, the split-screen control signal SW3 can be controlled to remain at low potential in display frames where all three sub-active areas are refreshed, enabling dual-side driving for the entire display screen, thereby enhancing the display effects.

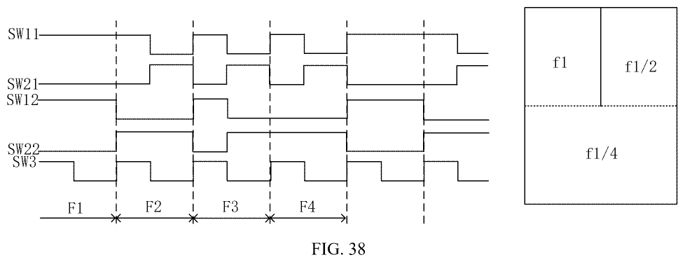

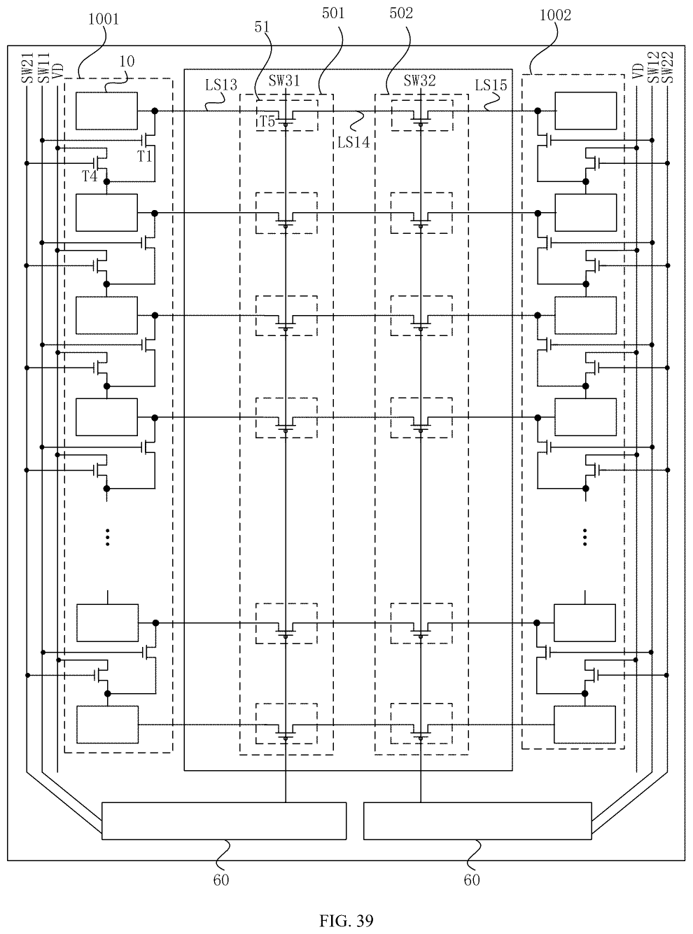

FIG. 38 is a schematic diagram of a driving timing sequence of a further display panel according to an embodiment of the present application, which corresponds to a display mode in which the display panel performs multi-frequency display in both the first direction and the second direction, for example, triple-split-screen multi-frequency display with left-right split-screens on the upper side and no left-right split-screen on the lower side. The driving process in this mode is similar to that in FIG. 37, where during each frame of display, the split-screen control signal SW3 undergoes a potential jump. By way of example, the upper-left sub-active area displays at a refresh frequency of f1, the upper-right sub-active area displays at a refresh frequency of f1/2, and the lower-side sub-active area displays at a refresh frequency of f1/4. During the scan time of the upper-side sub-active areas, the split-screen control signal SW3 remains at high potential, controlling all of the plurality of split-screen switch units 51 to remain turned off, thereby achieving single-side driving for each of the upper-left and upper-right two sub-active areas. During the driving process of the upper-side two sub-active areas, through the first-side first cascade control signal SW11 and the first-side switch control signal SW21, the sub-pixels in the upper-left-side sub-active area are controlled to refresh in each frame, and through the second-side first cascade control signal SW12 and the second-side switch control signal SW22, the sub-pixels in the upper-right-side sub-active area are controlled to refresh in odd-numbered frames. During the scan time of the lower-side sub-active area, the split-screen control signal SW3 remains at low potential, controlling all of the plurality of split-screen switch units 51 to remain turned on, thereby achieving dual-side driving of the lower-side sub-active area. During the driving process of the lower-side sub-active area, the outputs of the two first scan driving circuits remain consistent, for example, controlling the sub-pixels in the lower-side sub-active area to refresh once every 4 display frames.

In summary, by controlling whether the split-screen control signal SW3, the first cascade control signals on both sides, and the switch control signals on both sides perform potential jumps in each display frame, as well as controlling the potential jump time of the above control signals, the control of the split-screen mode of the display panel can be achieved to flexibly control the use of single-side driving or dual-side driving under different scenario modes. In the aforementioned implementations, the upper-lower dual-split-screen case is used as an example for illustration, but it is not intended to limit the present application. In practical applications, the number of upper-lower split-screens of the display panel and the refresh frequency of each partition can be set as needed. Furthermore, the frequency combinations provided in the aforementioned embodiments are merely illustrative. Actual frequency combinations can be customized as needed and are not limited to the several cases shown in the figures.

In one embodiment, the aforementioned implementations provide a control scheme in which the plurality of split-screen switch units 51 are in one-to-one correspondence with the first scan lines, but this is not intended to limit the present application. In other implementations, to achieve the split-screen multi-frequency display method shown in FIG. 37 or FIG. 38, the plurality of split-screen switch units 51 can also be arranged only at positions where left-right screen splitting is needed, while at positions where left-right screen splitting is not needed, the first scan lines are provided without segmentation.

On the basis of the aforementioned implementations, in one embodiment, the first sub-scan line LS11 has the same length as that of the second sub-scan line LS12, so that the parasitic resistance and other characteristic parameters of the two sub-scan lines are all of the same, ensuring that charging time for sub-pixels on both the left and right sides is consistent, thereby improving the display uniformity of the display panel.

The aforementioned implementations exemplarily provide a driving scheme for a display panel when a single split-screen control module is provided, which is not intended to limit the present application. In other implementations, the display panel may further be provided with a plurality of split-screen control modules. By means of on/off control of the split-screen control modules, the left-right split-screen positions of the display panel can be made more flexible. An example where two split-screen control modules are provided is used below for illustration.

FIG. 39 is a schematic diagram of a structure of a further display panel according to an embodiment of the present application. With reference to FIG. 39, by way of example, the first scan line includes three segments of sub-scan lines, namely the third sub-scan line LS13, the fourth sub-scan line LS14, and the fifth sub-scan line LS15. The display driver circuit includes: the first split-screen control module 501 and the second split-screen control module 502 are arranged sequentially in the second direction. The third sub-scan line LS13 is connected to the first-side first scan driving circuit 1001, the first split-screen control module 501 is connected between the third sub-scan line LS13 and the fourth sub-scan line LS14, the second split-screen control module 502 is connected between the fourth sub-scan line LS14 and the fifth sub-scan line LS15, and the fifth sub-scan line LS15 is connected to the second-side first scan driving circuit 1002. The split-screen control signal includes a first split-screen control signal SW31 and a second split-screen control signal SW32. Specifically, the first split-screen control module 501 is connected to the first split-screen control signal SW31, and the second split-screen control module 502 is connected to the second split-screen control signal SW32.

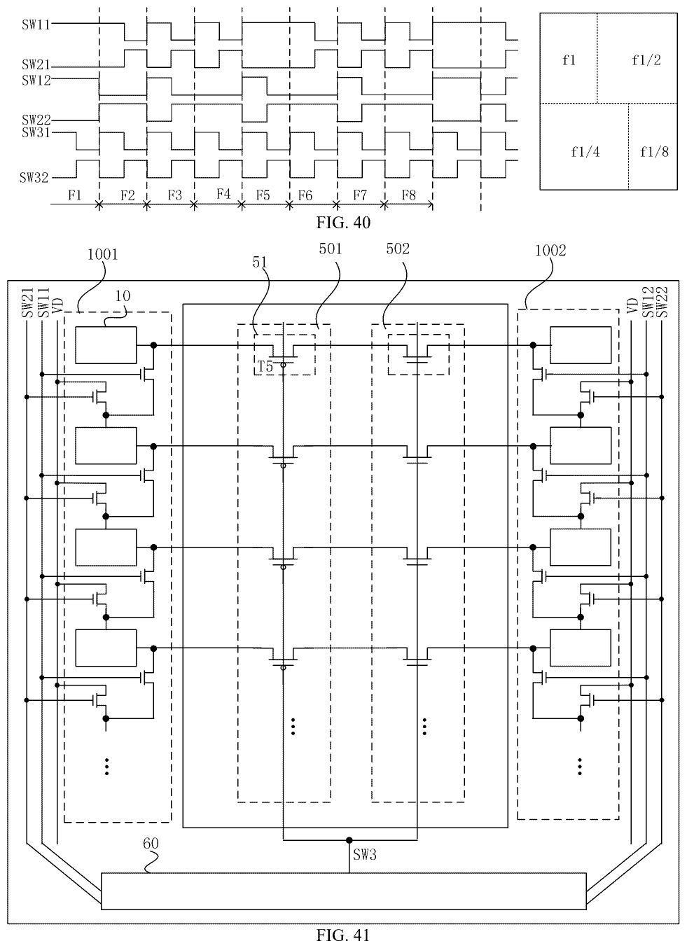

FIG. 40 is a schematic diagram of a driving timing sequence of a further display panel according to an embodiment of the present application, which corresponds to a display mode in which the display panel performs multi-frequency display in both the first direction and the second direction, for example, upper-lower-left-right quad-split-screen multi-frequency display. Compared to the display mode in FIG. 36, in this mode, the left-right split-screen positions are selectable for different rows of sub-pixels. By way of example, during the scan time of the upper-side two sub-active areas in each display frame, the first split-screen control signal SW31 remains at high potential and the second split-screen control signal SW32 remains at low potential, causing the first split-screen control module 501 to be turned off and the second split-screen control module 502 to be turned on. As a result, the upper-side left-right split-screen position is located at the position where the first split-screen control module 501 is provided. During the scan time of the lower-side two sub-active areas, the first split-screen control signal SW31 remains at low potential and the second split-screen control signal SW32 remains at high potential, causing the first split-screen control module 501 to be turned on and the second split-screen control module 502 to be turned off. As a result, the lower-side left-right split-screen position is located at the position where the second split-screen control module 502 is provided.

In this embodiment, by arranging a plurality of split-screen control modules 50, the adjustability of the left-right partition positions of the display panel can be achieved. The specific implementation process is as follows: within the same display frame, during a data writing process of part of the rows of pixel driver circuits, the first split-screen control module 501 is controlled to be turned on and the second split-screen control module 502 turned off, and during a data writing process of other rows of pixel driver circuits, the first split-screen control module 501 is controlled to be turned off and the second split-screen control module 502 turned on.

With continued reference to FIG. 39, on the basis of the aforementioned implementations, in one embodiment, the split-screen switch unit 51 includes: a fifth transistor T5, where a gate of the fifth transistor T5 is connected to the split-screen control signal, and a first electrode and a second electrode of the fifth transistor T5 are respectively connected to two adjacent sub-scan lines in the same first scan line. In one embodiment, the fifth transistor T5 may be a switch transistor so that the impedance thereof is relatively low when turned on, thereby reducing the load imposed on the driving circuit by the arrangement of the fifth transistor T5. By way of example, the width-to-length ratio and other dimensions of the fifth transistor T5 may be designed with reference to switch transistors in the pixel driver circuit.

By way of example, when the display driver circuit is provided with a plurality of split-screen control modules 50, the split-screen control modules 50 can use transistors with the same channel type, and the split-screen control modules 50 can be connected to different split-screen control signals. Alternatively, when two split-screen control modules 50 include transistors with different channel types, for example, as shown in FIG. 41, the first split-screen control module 501 includes a P-type transistor and the second split-screen control module 502 includes an N-type transistor, and the switch states of the two split-screen control modules 50 are opposite, the two split-screen control modules 501 and 502 may be connected to the same split-screen control signal SW3 to reduce the number of output ports of the driver IC, thereby reducing the costs.

It should be noted that the number of driver ICs 60 in the display panel can be set based on the actual requirements, for example, two driver ICs 60 are provided as shown in FIG. 39 or one driver IC 60 is arranged as shown in FIG. 41.

It should also be noted that the aforementioned implementations exemplarily show the case where the split-screen control modules are arranged between the segments of sub-scan lines of the first scan line, which is not intended to limit the present application. In other implementations, when the first shift registers are also connected to a second scan line, the second scan line may also be configured to include a plurality of sub-scan lines, and corresponding to the connection mode of the first scan line, split-screen control modules are also arranged between the sub-scan lines of the second scan line.

Embodiments of the present application further provide a control method for a display driver circuit, which is used to control the display driver circuit according to any embodiment of the present application, and has corresponding beneficial effects. The control method for the display driver circuit includes:
obtaining a target partition position of a display panel in a first direction (i.e., a column direction of sub-pixels); and
determining a cascade control signal during each frame of display based on the target partition position, and controlling a switch state of the cascade control module during each frame of display based on the cascade control signal.

In the control method for a display driver circuit according to an embodiment of the present application, the cascade control signal, by controlling the switch states of the plurality of cascade control modules, can control whether the turn-on potential of the scan signal output from the first shift register can be propagated stage by stage. By cutting off the transmission of the turn-on potential of the scan signal to a next-stage first shift register, a driving scheme for partitioned display within the same frame of display with the refresh frequency transitioning from high to low can be achieved. Furthermore, by arranging a plurality of cascade control modules, the position at which the transmission of the turn-on potential of the scan signal is cut off within each display frame is made adjustable, thereby allowing the partition positions for reduced-frequency display of the display panel to be adjustable. This enhances the display functionality of the display panel and makes the driving process of the display panel more flexible.

On the basis of the aforementioned implementations, in one embodiment, the at least one cascade control module includes a plurality of cascade control modules, and the display panel includes at least one target partition position. Thus, a display process of the display panel includes a plurality of types of display frames, where the plurality of types of display frames include a first active frame and at least one type of second active frame, with the type of the second active frame corresponding to the target partition position, respectively.

In the first active frame, the cascade control signal controls all of the plurality of cascade control modules to remain turned on. Therefore, in this type of display frame, the display panel is refreshed in full screen.

In the second active frame, the cascade control signal controls turn-off time of all of the plurality of cascade control modules, or controls a cascade control module at a preset position to be turned off, so that the display panel displays based on the target partition position corresponding to the second active frame, where sub-pixels above the target partition position are in an active frame, and sub-pixels below the target partition position are in an idle frame.

It should be noted that in various embodiments of the display driver circuit, specific descriptions of control methods are provided for different driver circuits. These control methods can all be considered as control methods for the driver circuit according to the embodiments of the present application, and the repeated content will not be reiterated here.

Embodiments of the present application further provide a display device, which includes a display driver circuit according to any of the embodiments of the present application, and has corresponding beneficial effects. By way of example, the display device includes a display panel according to any of the above embodiments, where the display driver circuit is disposed in the display panel. The display panel can be a display panel of a type such as an active-matrix organic light-emitting diode panel or a micro light-emitting diode display panel. The display device can be any product or component having a display function, such as a mobile phone, a tablet computer, a television, or a monitor.

It should be understood that the steps may be reordered, added, or deleted using the various forms of processes illustrated above. For example, the steps recorded in the present application may be performed in parallel, sequentially, or in a different order, provided that desired results of the embodiments of the present application can be achieved, which are not limited herein.

The above detailed description does not constitute a limitation on the scope of protection of the present application. Various modifications, combinations, sub-combinations, and substitutions can be made based on design requirements and other factors. Any modifications, equivalent substitutions, or improvements made within the spirit and principle of the present application should be included within the scope of protection of the present application.

1. A display driver circuit, comprising: at least one first scan driving circuit, wherein the at least one first scan driving circuit comprises:
a plurality of first shift registers arranged in cascade, each of the plurality of first shift registers comprising a register input terminal and a register output terminal, wherein the plurality of first shift registers are configured to output a plurality of scan signals; and
at least one cascade control module, the at least one cascade control module being connected between a current-stage register output terminal and a next-stage register input terminal, and the at least one cascade control module being connected to a cascade control signal, where the at least one cascade control module, in response to the cascade control signal, controls transmission of turn-on potential of the scan signal from the current-stage register output terminal to the next-stage register input terminal, so as to implement multi-frequency display of a display panel in a first direction.

2. The display driver circuit according to claim 1, wherein the at least one cascade control module comprises a plurality of cascade control modules, the plurality of cascade control modules being arranged respectively corresponding to at least part of the plurality of first shift registers in the at least one first scan driving circuit, and each of the plurality of cascade control modules being arranged between a corresponding current-stage first shift register and a corresponding next-stage first shift register in the at least part of the plurality of first shift registers; and the cascade control signal, by controlling switch states of the plurality of cascade control modules, adjusts a position at which the transmission of the turn-on potential of the scan signal to the next-stage register input terminal is cut off during one frame of display.

3. The display driver circuit according to claim 1, wherein the cascade control signal comprises:
a first cascade control signal; and
each of the plurality of cascade control modules comprises: a first transistor, wherein a first electrode of the first transistor is electrically connected to a corresponding current-stage register output terminal, and a second electrode of the first transistor is electrically connected to a corresponding next-stage register input terminal; and a gate of the first transistor is connected to the first cascade control signal, wherein turn-off time of the at least one cascade control module during one frame of display is determined based on potential jump time of the first cascade control signal during the one frame of display, thereby determining a partition position for reduced-frequency display of the display panel in the first direction.

4. The display driver circuit according to claim 2, wherein the cascade control signal comprises:
a plurality of second cascade control signals respectively corresponding to the plurality of cascade control modules;
each of the plurality of cascade control modules comprises: a second transistor, a gate of the second transistor being connected to a corresponding one of the plurality of second cascade control signals, and the second transistor being connected between a corresponding current-stage register output terminal and a corresponding next-stage register input terminal; and
wherein the at least one first scan driving circuit further comprises: a first power terminal and a second power terminal; and the at least one first scan driving circuit further comprises:
a first resistor string comprising a plurality of first resistors connected in series between the first power terminal and the second power terminal, with a plurality of first output terminals tapped from the first resistor string, wherein the plurality of first output terminals output the plurality of second cascade control signals; and the plurality of first output terminals are respectively connected to the plurality of cascade control modules, and at least one of the plurality of first resistors is disposed between two adjacent ones of the plurality of first output terminals,
wherein the cascade control signal further comprises: a plurality of third cascade control signals respectively corresponding to the plurality of cascade control modules;
each of the plurality of cascade control modules further comprises: a third transistor, a gate of the third transistor being connected to a corresponding one of the plurality of third cascade control signals, and the third transistor and the corresponding second transistor being connected in series between a corresponding current-stage register output terminal and a corresponding next-stage register input terminal; and wherein the at least one first scan driving circuit further comprises: a third power terminal and a fourth power terminal; and the at least one first scan driving circuit further comprises:
a second resistor string comprising a plurality of second resistors connected in series between the third power terminal and the fourth power terminal, with a plurality of second output terminals tapped from the second resistor string, wherein the plurality of second output terminals output the plurality of third cascade control signals; and the plurality of second output terminals are respectively connected to the plurality of cascade control modules, and at least one of the plurality of second resistors is disposed between two adjacent ones of the plurality of second output terminals; and
wherein during one frame of display, one of the plurality of cascade control modules at a preset position is turned off in response to the cascade control signal to control a partition position for reduced-frequency display of the display panel in the first direction, wherein adjustment of the preset position is implemented based on potential adjustment of the first power terminal, the second power terminal, the third power terminal, and the fourth power terminal.

5. The display driver circuit according to claim 1, wherein the at least one first scan driving circuit further comprises:
at least one auxiliary cut-off module, the at least one auxiliary cut-off module being arranged corresponding to the at least one cascade control module, wherein a control terminal of each of the at least one auxiliary cut-off module is connected to a switch control signal, an input terminal of each of the at least one auxiliary cut-off module is connected to an auxiliary cut-off signal, and an output terminal of each of the at least one auxiliary cut-off module is connected to the same register input terminal as one of the plurality of cascade control modules corresponding to the at least one auxiliary cut-off module,
wherein the at least one auxiliary cut-off module comprises a plurality of auxiliary cut-off modules, and the at least one cascade control module comprises a plurality of cascade control modules, the plurality of auxiliary cut-off modules being arranged respectively corresponding to the plurality of cascade control modules, and the plurality of auxiliary cut-off modules being connected to the same switch control signal, wherein on time of the plurality of auxiliary cut-off modules during one frame of display is determined based on potential jump time of the switch control signal during the one frame of display.

6. The display driver circuit according to claim 5, wherein the current-stage first shift register and the next-stage first shift register are respectively an i^{th}-stage first shift register and an (i+a)^{th}-stage first shift register, where i and a are both positive integers, wherein in a case where the i^{th}-stage first shift register outputs turn-on potential of an i^{th}-stage scan signal and the (i+a)^{th}-stage first shift register outputs turn-on potential of an (i+a)^{th}-stage scan signal, during a phase when the i^{th}-stage first shift register outputs the turn-on potential of the i^{th}-stage scan signal, the cascade control signal controls one of the plurality of cascade control modules between the i^{th}-stage first shift register and the (i+a)^{th}-stage first shift register to be turned on, and the switch control signal controls one of the at least one auxiliary cut-off module between the i^{th}-stage first shift register and the (i+a)^{th}-stage first shift register to be turned off; and
in a case where the i^{th}-stage first shift register outputs the turn-on potential of the i^{th}-stage scan signal and the (i+a)^{th}-stage first shift register outputs cutoff potential of the (i+a)^{th}-stage scan signal, during the phase when the i^{th}-stage first shift register outputs the turn-on potential of the i^{th}-stage scan signal, the cascade control signal controls the one of the plurality of cascade control modules between the i^{th}-stage first shift register and the (i+a)^{th}-stage first shift register to be turned off, and the switch control signal controls the one of the at least one auxiliary cut-off module between the i^{th}-stage first shift register and the (i+a)^{th}-stage first shift register to be turned on.

7. The display driver circuit according to claim 5, further comprising: a first potential signal line and a second potential signal line, the first potential signal line being configured to provide a first potential signal to the plurality of first shift registers, and the second potential signal line being configured to provide a second potential signal to the plurality of first shift registers, wherein
when the potential of the first potential signal is cutoff potential, the first potential signal is reused as the auxiliary cut-off signal; and when the potential of the second potential signal is the cutoff potential, the second potential signal is reused as the auxiliary cut-off signal.

8. The display driver circuit according to claim 5, wherein the cascade control signal comprises:
a first cascade control signal; and each of the at least one cascade control module comprises: a first transistor, wherein a gate of the first transistor is connected to the first cascade control signal, a first electrode of the first transistor is electrically connected to a corresponding current-stage register output terminal, and a second electrode of the first transistor is electrically connected to a corresponding next-stage register input terminal; and
each of the at least one auxiliary cut-off module comprises: a fourth transistor, wherein a gate of the fourth transistor is connected to the switch control signal, a first electrode of the fourth transistor is connected to the auxiliary cut-off signal, and a second electrode of the fourth transistor is electrically connected to a corresponding next-stage register input terminal, wherein the first transistor has the same channel type as that of the fourth transistor, and the first cascade control signal has an opposite phase to that of the switch control signal; or
the first transistor has a different channel type from that of the fourth transistor, and the first cascade control signal is reused as the switch control signal; or
the first transistor has the same channel type as that of the fourth transistor, and the first cascade control signal is reused as the auxiliary cut-off signal.

9. The display driver circuit according to claim 1, further comprising: a plurality of pixel driver circuits and a plurality of first scan lines, wherein the plurality of pixel driver circuits are arranged in an array, and each row of the plurality of pixel driver circuits is electrically connected to at least one of the plurality of first scan lines; and the register output terminal in the at least one first scan driving circuit is electrically connected to one of the plurality of first scan lines, wherein each of the plurality of pixel driver circuits comprises: a driving module, a data writing module, a threshold compensation module, and a light emission control module, wherein the driving module is connected between the light emission control module and a light-emitting device, and the driving module is configured to generate a driving current; the data writing module is electrically connected to a first terminal of the driving module, and the data writing module is configured to transmit a data voltage to the driving module; the threshold compensation module is connected between a control terminal and a second terminal of the driving module, and the threshold compensation module is configured to compensate for a threshold voltage of the driving module; and one of the plurality of first scan lines is electrically connected to a control terminal of the threshold compensation module in a corresponding row of the plurality of pixel driver circuits, wherein each of the plurality of pixel driver circuits further comprises: a first reset module electrically connected to the control terminal of the driving module, the first reset module being configured to reset the control terminal of the driving module; and the display driver circuit further comprises: a plurality of second scan lines, each of the plurality of second scan lines being electrically connected to a control terminal of the first reset module in a corresponding row of the plurality of pixel driver circuits, wherein the register output terminals in the at least one first scan driving circuit are electrically connected to the plurality of second scan lines, wherein one of the plurality of second scan lines connected to a j^{th} row of the plurality of pixel driver circuits is electrically connected to a j^{th}-stage register output terminal, and one of the plurality of first scan lines connected to the j^{th} row of the plurality of pixel driver circuits is electrically connected to a (j+b)^{th}-stage register output terminal, where j and b are both positive integers.

10. The display driver circuit according to claim 9, wherein each of the plurality of pixel driver circuits further comprises: a first reset module electrically connected to the control terminal of the driving module, the first reset module being configured to reset the control terminal of the driving module; and the display driver circuit further comprises: a plurality of second scan lines, each of the plurality of second scan lines being electrically connected to a control terminal of the first reset module in a corresponding row of the plurality of pixel driver circuits,
wherein the register output terminals in the at least one first scan driving circuit are electrically connected to the plurality of second scan lines, wherein one of the plurality of second scan lines connected to a j^{th} row of the plurality of pixel driver circuits is electrically connected to a j^{th}-stage register output terminal, and one of the plurality of first scan lines connected to the j^{th} row of the plurality of pixel driver circuits is electrically connected to a (j+b)^{th}-stage register output terminal, where j and b are both positive integers.

11. The display driver circuit according to claim 9, wherein the at least one first scan driving circuit comprises a first-side first scan driving circuit and a second-side first scan driving circuit, the first-side first scan driving circuit and the second-side first scan driving circuit being respectively disposed on two sides of the plurality of pixel driver circuits; and the plurality of first shift registers of corresponding stages in the first-side first scan driving circuit and the second-side first scan driving circuit being connected to the same one of the plurality of first scan lines;
each of at least part of the plurality of first scan lines comprises at least two sub-scan lines; and
the display driver circuit further comprises: at least one split-screen control module, the at least one split-screen control module comprising a plurality of split-screen switch units, wherein the plurality of split-screen switch units are arranged respectively corresponding to the at least part of the plurality of first scan lines; each of the plurality of split-screen switch units is connected between two adjacent sub-scan lines in the same one of the plurality of first scan lines; and when each of the plurality of split-screen switch units is turned off in response to a split-screen control signal, the first-side first scan driving circuit and the second-side first scan driving circuit respectively transmit scan signals to sub-scan lines on both sides of the plurality of split-screen switch units.

12. The display driver circuit according to claim 11, wherein at the same moment, the number of the plurality of split-screen switch units on the same one of the plurality of first scan lines that are in an off state is less than or equal to one; and
the plurality of split-screen switch units in the same one of the at least one split-screen control module are connected to the same split-screen control signal.

13. The display driver circuit according to claim 12, wherein a cascade control signal connected to the first-side first scan driving circuit is a first-side cascade control signal, and a cascade control signal connected to the second-side first scan driving circuit is a second-side cascade control signal, the first-side cascade control signal being different from the second-side cascade control signal.

14. The display driver circuit according to claim 11, wherein when turn-on potential of scan signals is simultaneously transmitted on two sub-scan lines respectively connected to both ends of one split-screen switch unit among the plurality of split-screen switch units, the split-screen control signal controls the one split-screen switch unit among the plurality of split-screen switch units to be turned on.

15. The display driver circuit according to claim 11, wherein each of the at least part of the plurality of first scan lines comprises a first sub-scan line and a second sub-scan line, the first sub-scan line being connected to the first-side first scan driving circuit, and the second sub-scan line being connected to the second-side first scan driving circuit; and
each of the plurality of split-screen switch units is separately electrically connected to a corresponding first sub-scan line and second sub-scan line.

16. The display driver circuit according to claim 11, wherein each of the at least part of the plurality of first scan lines comprises a third sub-scan line, a fourth sub-scan line, and a fifth sub-scan line; and the at least one split-screen control module comprises: a first split-screen control module and a second split-screen control module, wherein the third sub-scan line is connected to the first-side first scan driving circuit, the first split-screen control module is connected between the third sub-scan line and the fourth sub-scan line, the second split-screen control module is connected between the fourth sub-scan line and the fifth sub-scan line, and the fifth sub-scan line is connected to the second-side first scan driving circuit,
wherein within the same display frame, during a data writing process of part of the rows of the plurality of pixel driver circuits, the first split-screen control module is turned on and the second split-screen control module is turned off, and during a data writing process of other rows of the plurality of pixel driver circuits, the first split-screen control module is turned off and the second split-screen control module is turned on, and
wherein the split-screen control signal comprises a first split-screen control signal and a second split-screen control signal, the first split-screen control module being connected to the first split-screen control signal, and the second split-screen control module being connected to the second split-screen control signal; and a transistor in one of the plurality of split-screen switch units in the first split-screen control module has a different channel type from that of a transistor in one of the plurality of split-screen switch units in the second split-screen control module, and the first split-screen control signal is reused as the second split-screen control signal.

17. The display driver circuit according to claim 11, wherein each of the plurality of split-screen switch units comprises: a fifth transistor, wherein a gate of the fifth transistor is connected to the split-screen control signal, and a first electrode of the fifth transistor and a second electrode of the fifth transistor are respectively connected to two adjacent sub-scan lines in the same one of the plurality of first scan lines.

18. A control method for a display driver circuit, which is used to control the display driver circuit, comprising:
at least one first scan driving circuit,
wherein the at least one first scan driving circuit comprises:
a plurality of first shift registers arranged in cascade, each of the plurality of first shift registers comprising a register input terminal and a register output terminal, wherein the plurality of first shift registers are configured to output a plurality of scan signals; and
at least one cascade control module, the at least one cascade control module being connected between a current-stage register output terminal and a next-stage register input terminal, and the at least one cascade control module being connected to a cascade control signal, where the at least one cascade control module, in response to the cascade control signal, controls transmission of turn-on potential of the scan signal from the current-stage register output terminal to the next-stage register input terminal, so as to implement multi-frequency display of a display panel in a first direction,
the control method comprising:
obtaining a target partition position of a display panel in a first direction; and
determining a cascade control signal during each frame of display based on the target partition position, and controlling a switch state of the cascade control module during each frame of display based on the cascade control signal.

19. The control method for a display driver circuit according to claim 18, wherein the at least one cascade control module comprises a plurality of cascade control modules; the display panel comprises at least one target partition position; and
a display process of the display panel comprises a plurality of types of display frames, the plurality of types of display frames comprise a first active frame and at least one type of second active frame, with the type of the at least one type of second active frame corresponding to the at least one target partition position, respectively, wherein in the first active frame, the cascade control signal controls all of the plurality of cascade control modules to remain turned on; and
in the second active frame, the cascade control signal controls turn-off time of all of the plurality of cascade control modules, or controls one of the plurality of cascade control modules at a preset position to be turned off, so that the display panel displays based on the target partition position corresponding to the second active frame.

20. A display device, comprising:
a display driver circuit, comprising:
at least one first scan driving circuit,
wherein the at least one first scan driving circuit comprises:
a plurality of first shift registers arranged in cascade, each of the plurality of first shift registers comprising a register input terminal and a register output terminal, wherein the plurality of first shift registers are configured to output a plurality of scan signals; and
at least one cascade control module, the at least one cascade control module being connected between a current-stage register output terminal and a next-stage register input terminal, and the at least one cascade control module being connected to a cascade control signal, where the at least one cascade control module, in response to the cascade control signal, controls transmission of turn-on potential of the scan signal from the current-stage register output terminal to the next-stage register input terminal, so as to implement multi-frequency display of a display panel in a first direction; and
a display panel, wherein the display driver circuit is disposed in the display panel.
